(19) United States
(12) Patent Application Publication
(10) Pub. No.: US 2026/0033076 A1
(43) Pub. Date: Jan. 29, 2026

(54) DISPLAY PANEL AND DISPLAY DEVICE COMPRISING THE SAME

(71) Applicant: LG Display Co., Ltd., Seoul (KR)

(72) Inventors: Jeen Wook KWON, Paju-si (KR); Kyoung June JUNG, Paju-si (KR); Dae Han WON, Paju-si (KR); Chan Woo IM, Paju-si (KR)

(73) Assignee: LG Display Co., Ltd., Seoul (KR)

(21) Appl. No.: 19/232,039

(22) Filed: Jun. 9, 2025

(30) Foreign Application Priority Data
Jul. 26, 2024 (KR) 10-2024-0099193

(51) Int. Cl. H10H 29/49

(52) U.S. Cl. CPC H10H 29/49

(57) ABSTRACT

The present specification provides a display panel and a display device including the same, and the display panel includes a circuit layer disposed on a substrate and a plurality of light emitting diodes disposed on the circuit layer, wherein the circuit layer includes a plurality of driving lines disposed on the substrate and electrically connected to the light emitting diodes disposed in a display area among the plurality of light emitting diodes and a plurality of non-driving lines disposed on the substrate in a non-display area outside the display area, and at least one of the non-driving lines includes a plurality of dummy floating lines electrically separated from the light emitting diodes and the driving lines.

### CROSS-REFERENCE TO RELATED APPLICATION

This application claims priority to and the benefit of Korean Patent Application No. 10-2024-0099193, filed on Jul. 26, 2024, the disclosure of which is incorporated herein by reference in its entirety.

### BACKGROUND

### Technical Field

The present specification relates to a display panel and a display device including the same.

### Description of the Related Art

Display devices are applied to various electronic devices such as a television (TV), a mobile phone, a laptop, and a tablet.

Display devices include an organic light emitting display (OLED) or the like that emits light by itself and a liquid crystal display (LCD) or the like that needs a separate light source.

In recent years, a display device including a light emitting diode (LED) has gained attention as a next-generation display device. Due to being made of an inorganic material rather than an organic material, an LED has a faster lighting speed, has higher luminous efficiency, and can display an image with higher brightness compared to an LCD or an OLED.

In transfer of inorganic light emitting diodes of a display device, during the transfer in the vicinity of a non-display area in which an image is not output, due to a step difference between the non-display area and a display area, a light emitting diode may not be transferred into the display area, and reliability may decrease.

In addition, moisture or the like may penetrate from the outside into a display device including inorganic light emitting diodes. When external particles such as the penetrating moisture or the like are accumulated inside the display device, technical problems such as a decrease in reliability may occur.

### BRIEF SUMMARY

As inventors recognized, in a display device including inorganic light emitting diodes (micro light emitting diodes (micro LEDs)), a light emitting diode may not be transferred to a display area disposed in the vicinity of a non-display area, and the reliability of the display device may decrease.

Embodiments of the present specification provide a display panel and a display device including the same with improved process reliability.

Embodiments of the present specification provide a display panel and a display device including the same with improved operational reliability.

Features of embodiments of the present specification are not limited to the above-mentioned features, and other unmentioned features should be clearly understood by those of ordinary skill in the art from the description below.

A display panel according to an embodiment of the present specification may include a circuit layer disposed on a substrate and a plurality of light emitting diodes disposed on the circuit layer, wherein the circuit layer may include a plurality of driving lines disposed on the substrate and electrically connected to the light emitting diodes disposed in a display area among the plurality of light emitting diodes and a plurality of non-driving lines disposed on the substrate in a non-display area outside the display area, and at least one of the non-driving lines may include a plurality of dummy floating lines electrically separated from the light emitting diodes and the driving lines.

Detailed matters according to various embodiments of the present specification, except for the solutions to the problems as described above, are included in the following description and the accompanying drawings.

### BRIEF DESCRIPTION OF THE SEVERAL VIEWS OF THE DRAWINGS

The above and other objects, features, and advantages of the present specification will become more apparent to those of ordinary skill in the art by describing exemplary embodiments thereof in detail with reference to the accompanying drawings, in which:

FIG. 1 is an exploded perspective view of a display device according to an embodiment of the present specification;

FIG. 2 is a plan view illustrating the display device according to an embodiment of the present specification;

FIG. 3 is an enlarged view illustrating the display device according to an embodiment of the present specification;

FIG. 4 is a plan view illustrating the display device according to an embodiment of the present specification;

FIG. 5 is a view illustrating a circuit structure according to an embodiment of the present specification;

FIG. 6 is a partially enlarged view showing portion A of FIG. 3 in an enlarged manner;

FIG. 7 is an enlarged view of a display area including a single pixel of FIG. 6;

FIG. 8 is a partially enlarged view showing portion A of FIG. 3 in an enlarged manner;

FIG. 9 is a cross-sectional view of the display device according to an embodiment of the present specification that is along line I-I′ of FIG. 4;

FIG. 10 is a cross-sectional view illustrating a subpixel including a light emitting diode disposed in a display area AA;

FIG. 11 is a partially enlarged view showing portion B of FIG. 3 in an enlarged manner;

FIG. 12 is a cross-sectional view of the display device according to an embodiment of the present specification that is along line II-II′ of FIG. 11;

FIG. 13 is a cross-sectional view of the display device according to a second embodiment of the present specification that is along line II-II′ of FIG. 11;

FIG. 14 is a cross-sectional view of the display device according to a third embodiment of the present specification that is along line II-II′ of FIG. 11;

FIG. 15 is a view illustrating a device to which the display device according to embodiments of the present specification is applied;

FIG. 16 is a view illustrating a device to which the display device according to embodiments of the present specification is applied;

FIG. 17 is a view illustrating a device to which the display device according to embodiments of the present specification is applied; and

FIG. 18 is a view illustrating a device to which the display device according to embodiments of the present specification is applied.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted. The terms such as “comprising,” “including,” “having” and “consisting of” used herein are generally intended to allow other components to be added unless the terms are used with the term “only,” References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to,’ and the like, one or more other parts may be located between the two parts unless ‘immediately’ or ‘directly’ is used.

When describing a temporal contextual relationship is described, such as “after,” “following,” “next to,” or “before,” it may also include non-contiguous cases unless “immediately” or “directly” is used.

In the description for the embodiments, the first, second, etc., are used to describe various components, but these components are not limited by these terms. These terms are only used to distinguish one component from another. Therefore, the first component mentioned below may be a second component within the technical spirit of the present disclosure.

Terms such as first, second, A, B, (a), (b), and the like may be used to describe elements of the embodiments of the present specification. Such terms are intended only to distinguish one component from another and are not intended to define the nature, sequence, order, or number of such components.

When a component is described as “connected,” “coupled,” or “attached” to another component, it is to be understood that the component may be directly connected or attached to the another component, but that there may also be other components “interposed” between the respective components which may be indirectly connected or attached where not specifically stated.

When a component or layer is described as “contacting” or “overlapping” another component or layer, the component or layer may directly contact or overlap the other component or layer, but unless there is a specific statement, it should be understood that other components may be interposed between the components that are indirectly contacting or overlapping.

It should be understood that the term “at least one” includes all possible combinations of one or more related components. For example, the meaning of “at least one of the first, second, and third components” includes not only the first, second, or third component, but also any combination of two or more of the first, second, and third components.

“First direction,” “second direction,” “third direction,” “X-axis direction,” “Y-axis direction,” and “Z-axis direction” should not be interpreted only as geometric relationships that are perpendicular to each other, but may mean a broader directionality within the range that the configuration of the present specification may function.

The following embodiments may be combined or associated with each other in whole or in part, and various types of interlocking and driving are technically possible. The embodiments may be implemented independently of each other or together in an interrelated relationship.

Hereinafter, example embodiments of the present disclosure will be described in detail with reference to the accompanying drawings.

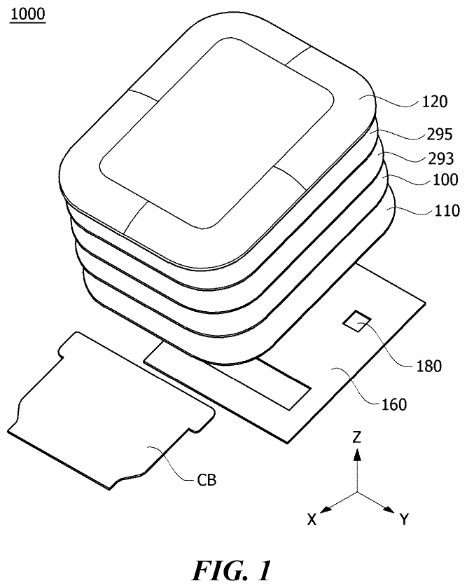

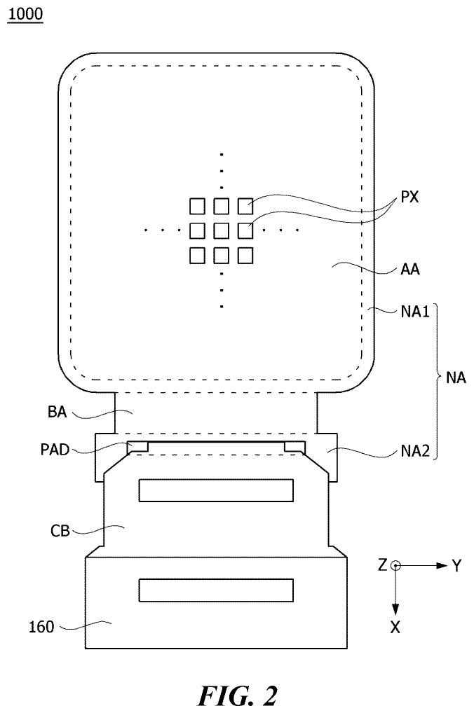

FIG. 1 is an exploded perspective view illustrating a display device according to an embodiment of the present specification. FIG. 2 is a plan view illustrating the display device according to an embodiment of the present specification.

Referring to FIGS. 1 and 2, a display device 1000 according to an embodiment of the present specification may include a display panel 100, a polarizing layer 293, an adhesive layer 295, a cover member 120, a support substrate 110, a flexible circuit board CB, and a printed circuit board 160.

For example, the display device 1000 may include a substrate 110. The substrate 110 may be a member supporting other components of the display device 1000. The substrate 110 may be made of an insulating material. For example, the substrate 110 may be made of glass, resin, or the like. In addition, the substrate 110 may be made of a material having flexibility. For example, the substrate 110 may be made of a plastic material having flexibility such as polyimide (PI). However, embodiments of the present specification are not limited thereto.

The display panel 100 may implement information, a video, and/or an image provided to a user. For example, the display panel 100 may include a display area AA and a non-display area NA. For example, the substrate 110 may include the display area AA and the non-display area NA. The display area AA and the non-display area NA may be described for the display device 1000 as a whole instead of being described only for the substrate 110.

The display area AA may be an area in which an image is displayed. The display area AA may include a plurality of pixels PX. The plurality of pixels PX may each be made of a plurality of subpixels. The plurality of subpixels may each have a plurality of light emitting diodes disposed thereon. The plurality of light emitting diodes may be configured differently according to the type of the display device 1000. For example, when the display device 1000 is an inorganic light emitting display device, the light emitting diodes may be light-emitting diodes (LEDs), micro light-emitting diodes (micro LEDs), or mini light-emitting diodes (mini LEDs), but embodiments of the present specification are not limited thereto.

The non-display area NA may be an area in which an image is not displayed. Various lines, circuits, and the like for driving the plurality of pixels PX of the display area AA may be disposed in the non-display area NA. For example, various lines and driving circuits may be mounted on the non-display area NA, and a pad portion PAD to which an integrated circuit, a printed circuit, and the like are connected may be disposed in the non-display area NA, but the embodiments of the present specification are not limited thereto.

For example, a driving circuit may be a data driving circuit and/or a gate driving circuit, but the embodiments of the present specification are not limited thereto. Lines to which a control signal for controlling driving circuits is supplied may be disposed on the display panel 100. For example, the control signal may include various timing signals including a clock signal, an input data enable signal, and synchronization signals, but the embodiments of the present specification are not limited thereto. The control signal may be received through the pad portion PAD. For example, link lines LL for transmitting a signal may be disposed in the non-display area NA. For example, a driving part such as the flexible circuit board CB and the printed circuit board 160 may be connected to the pad portion PAD.

According to the present specification, the non-display area NA may include a first non-display area NA1, a bending area BA, and a second non-display area NA2. For example, the first non-display area NA1 may be an area surrounding at least a portion of the display area AA. The bending area BA may be a bendable area that extends from at least any one side among a plurality of sides of the first non-display area NA1. The second non-display area NA2 may be an area extending from the bending area BA, and the pad portion PAD may be disposed in the second non-display area NA2. For example, the bending area BA may be in a bent state, and the remaining areas of the substrate 110 except for the bending area BA may be in a flat state. In this case, as the bending area BA is bent, the second non-display area NA2 may be located on a back surface of the display area AA. However, the embodiments of the present specification are not limited thereto.

The display area AA of the substrate 110 or the display device 1000 may be configured in various shapes according to the design of the display device 1000. For example, the display area AA may be configured in a rectangular shape with four round corners, but the embodiments of the present specification are not limited thereto. In another example, the display area AA may be configured in a rectangular shape with four right-angled corners or a circular shape, but the embodiments of the present specification are not limited thereto.

According to the present specification, a width of the second non-display area NA2 in which a plurality of pad electrodes PE are disposed may be wider than a width of the bending area BA in which only the plurality of link lines LL are disposed. In addition, a width of the display area AA in which the plurality of subpixels are disposed may be wider than the width of the bending area BA in which only the plurality of link lines LL are disposed. Although the width of the bending area BA is illustrated as being narrower than the widths of other areas of the substrate 110 in the drawings, the shape of the substrate 110 including the bending area BA is only illustrative, and the embodiments of the present specification are not limited thereto.

The flexible circuit board CB and the printed circuit board 160 may be disposed at a lower portion of the display panel 100. The flexible circuit board CB and the printed circuit board 160 may be disposed at least on one side edge of the display panel 100, but the embodiments of the present specification are not limited thereto. One side of the flexible circuit board CB may be attached to the display panel 100 and the other side thereof may be attached to the printed circuit board 160, but the embodiments of the present specification are not limited thereto. The flexible circuit board CB may be a flexible film, but the embodiments of the present specification are not limited thereto.

The pad portion PAD including the plurality of pad electrodes PE may be disposed in the second non-display area NA2. Driving parts including one or more flexible circuit boards (or flexible films) CB and the printed circuit board 160 may be attached or bonded to the pad portion PAD. The plurality of pad electrodes PE of the pad portion PAD may be electrically connected to the one or more flexible circuit boards (or flexible films) CB and may transmit various signals (or power) from the printed circuit board 160 and the flexible circuit board (or flexible film) CB to a plurality of pixel driving circuits PD of the display area AA.

The flexible circuit board (or flexible film) CB may be a film in which various parts are disposed on a base film having flexibility. For example, a driving integrated circuit (IC) such as a gate driver IC or a data driver IC may be disposed on the flexible circuit board (or flexible film) CB, but the embodiments of the present specification are not limited thereto. The driving IC may be a part that processes data and driving signals for displaying an image. The driving IC may be disposed in a manner such as a chip-on-glass (COG) manner, a chip-on-film (COF) manner, or a tape carrier package (TCP) manner according to a manner in which the driving IC is mounted, but the embodiments of the present specification are not limited thereto. The flexible circuit board (or flexible film) CB may be attached or bonded onto the plurality of pad electrodes PE through a conductive adhesive layer, but the embodiments of the present specification are not limited thereto.

The printed circuit board 160 may be a part that is electrically connected to the one or more flexible circuit boards (or flexible films) CB and supplies a signal to the driving IC. The printed circuit board 160 may be disposed on one side of the flexible circuit board (or flexible film) CB and may be electrically connected to the flexible circuit board (or flexible film) CB. Various parts for supplying various signals to the driving IC may be disposed on the printed circuit board 160. For example, various parts such as a timing controller, a power supply, a memory, or a processor may be disposed on the printed circuit board 160. For example, the printed circuit board 160 may include a power management integrated circuit (PMIC), but the embodiments of the present specification are not limited thereto.

The printed circuit board 160 may include at least one hole 180, but the embodiments of the present specification are not limited thereto. An internal component that detects ambient light, a temperature, or the like and may be provided as a plurality of sensors may be disposed in an area that corresponds to the at least one hole 180. For example, the internal component may include an ambient light sensor (ALS), a temperature sensor, or the like, but the embodiments of the present specification are not limited thereto. For example, the hole 180 may be a through-hole or the like, but the embodiments of the present specification are not limited thereto.

The polarizing layer 293 may be disposed on the display panel 100. The polarizing layer 293 may prevent or reduce a phenomenon in which light generated from an external light source enters the display panel 100 and affects the light emitting diodes or the like.

The cover member 120 may be disposed on the polarizing layer 293. The cover member 120 may be a member for protecting the display panel 100. The adhesive layer 295 may be disposed between the polarizing layer 293 and the cover member 120. The cover member 120 may be attached to the polarizing layer 293 by the adhesive layer 295. The adhesive layer 295 may include an optically clear adhesive (OCA), an optically clear resin (OCR), a pressure sensitive adhesive (PSA), or the like, but the embodiments of the present specification are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present specification are not limited thereto.

The plurality of link lines LL may be disposed in the non-display area NA. The plurality of link lines LL may be lines that transmit various signals from the one or more flexible circuit boards (or flexible films) CB and the printed circuit board 160 to the display area AA. The plurality of link lines LL may extend from the plurality of pad electrodes PE in the second non-display area NA2 toward the bending area BA and the first non-display area NA1 and may be electrically connected to a plurality of driving lines VL in the display area AA. The plurality of pixel driving circuits PD may be driven by receiving a signal from the one or more flexible circuit boards (or flexible films) CB and the printed circuit board 160 through the driving lines VL of the display area AA and the link lines LL of the non-display area NA.

For example, the plurality of driving lines VL may be lines for transmitting a signal output from the flexible circuit board (or flexible film) CB and the printed circuit board 160 to the plurality of pixel driving circuits PD together with the plurality of link lines LL. The plurality of driving lines VL may be disposed in the display area AA and may each be electrically connected to one of the plurality of pixel driving circuits PD. The plurality of driving lines VL may extend from the display area AA toward the non-display area NA and may be electrically connected to the plurality of link lines LL. Accordingly, the signal output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, one portion of the plurality of link lines LL may also be bent. Stress may be concentrated to the one portions of the link lines LL that is bent, and accordingly, cracks may be formed in the link lines LL. Thus, the plurality of link lines LL may be made of a conductive material with excellent flexibility to reduce cracks when the bending area BA is bent. For example, the plurality of link lines LL may be made of a conductive material with excellent flexibility such as gold (Au), silver (Ag), and aluminum (Al), but the embodiments of the present specification are not limited thereto. In addition, the plurality of link lines LL may also be made of one of various conductive materials used in the display area AA. For example, the plurality of link lines LL may be made of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto. The plurality of link lines LL may be made of a multilayer structure including various conductive materials. For example, the plurality of link lines LL may be made of a triple layer structure of titanium (Ti)/aluminum (Al)/titanium (Ti), but the embodiments of the present specification are not limited thereto.

The plurality of link lines LL may be configured in various shapes to reduce stress. At least one portion of the plurality of link lines LL disposed on the bending area BA may extend in the same direction as an extending direction of the bending area BA or may extend in a different direction from the extending direction of the bending area BA to reduce stress. For example, in a case in which the bending area BA extends in one direction from the first non-display area NA1 toward the second non-display area NA2, at least one portion of the link lines LL disposed on the bending area BA may extend in a direction inclined from the one direction. In another example, at least one portion of the plurality of link lines LL may be configured in patterns of various shapes. For example, at least one portion of the plurality of link lines LL disposed on the bending area BA may have a shape in which a conductive pattern having at least one of a diamond shape, a rhombic shape, a trapezoidal wave shape, a triangular wave shape, a sawtooth wave shape, a sinusoidal wave shape, a circular shape, and an omega (Ω) shape is repeatedly arranged, but the embodiments of the present specification are not limited thereto. Accordingly, in order to minimize the stress concentrated to the plurality of link lines LL and cracks caused thereby, the plurality of link lines LL may be formed in various shapes including the above-listed shapes, but the embodiments of the present specification are not limited thereto.

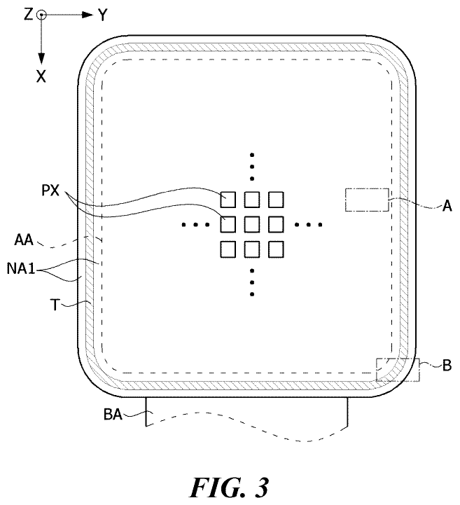

FIG. 3 is an enlarged view illustrating the display device according to an embodiment of the present specification.

Referring to FIG. 3, the first non-display area NA1 may include an area in which a trench T is disposed. The area in which the trench T is disposed may be formed to have a shape that is substantially the same as the shape of the first non-display area NA1. For example, the first non-display area NA1 may have a rectangular shape with four round corners as will be described below. In this case, the area in which the trench T is disposed may have a rectangular shape with four round corners. An area of the rectangular shape formed of an outermost periphery of the area in which the trench T is disposed may be smaller than an area of the rectangular shape formed of an outermost periphery of the first non-display area NA1. The area in which the trench T is formed may be disposed to surround a plurality of pixels PX.

In one embodiment, the display area AA may include an area in which a trench Tis formed. The area in which the trench T is formed may be disposed to surround a plurality of pixels PX.

The trench T may be disposed to surround the plurality of pixels PX. At least one portion of the trench T may be disposed between a plurality of light emitting diodes. The plurality of light emitting diodes may be disposed in the display area AA and/or the first non-display area NA1. The trench T may be disposed between the display area AA and the bending area BA. The trench T may be disposed between the display panel 100 and the bending area BA. The trench T may be disposed between at least one portion of the display panel 100 and the bending area BA.

The display area AA of the substrate 110 or the display device 1000 may be configured in various shapes according to the design of the display device 1000. For example, the display area AA may be configured in a rectangular shape with four round corners, but the embodiments of the present specification are not limited thereto. In another example, the display area AA may be configured in a rectangular shape with four right-angled corners or a circular shape, but the embodiments of the present specification are not limited thereto.

According to the present specification, a width of the second non-display area NA2 in which a plurality of pad electrodes PE are disposed may be wider than a width of the bending area BA in which only the plurality of link lines LL are disposed. In addition, a width of the display area AA in which the plurality of subpixels are disposed may be wider than the width of the bending area BA in which only the plurality of link lines LL are disposed. Although the width of the bending area BA is illustrated as being narrower than the widths of other areas of the substrate 110 in the drawings, the shape of the substrate 110 including the bending area BA is only illustrative, and the embodiments of the present specification are not limited thereto.

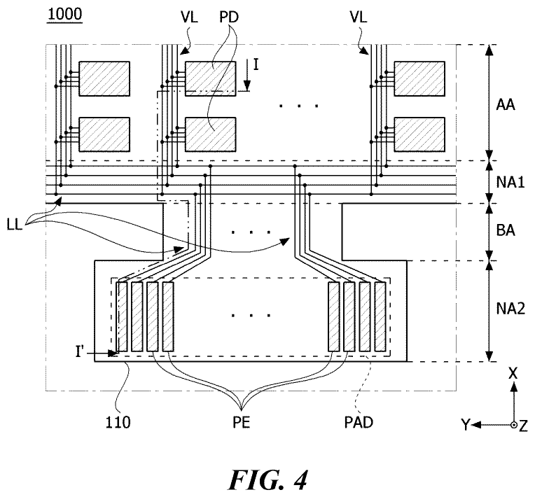

FIG. 4 is a plan view illustrating the display device according to an embodiment of the present specification.

Referring to FIG. 4, a plurality of pixel driving circuits PD may be disposed in the display area AA. The plurality of pixel driving circuits PD may be circuits for driving the light emitting diodes of the plurality of subpixels. The plurality of pixel driving circuits PD may each include a plurality of transistors including a driving transistor, a storage capacitor, and the like and may supply a control signal, power, and driving current to the light emitting diodes of the plurality of subpixels to control a light emitting operation of the plurality of light emitting diodes. For example, the pixel driving circuit PD may include a power line and a signal line for controlling light emission on/off and/or light emission time of the light emitting diodes. For example, the plurality of pixel driving circuits PD may be drivers manufactured using a metal-oxide-silicon field effect transistor (MOSFET) manufacturing process on a semiconductor substrate, but the embodiments of the present specification are not limited thereto. A driver may include the plurality of pixel driving circuits PD and may drive the plurality of subpixels.

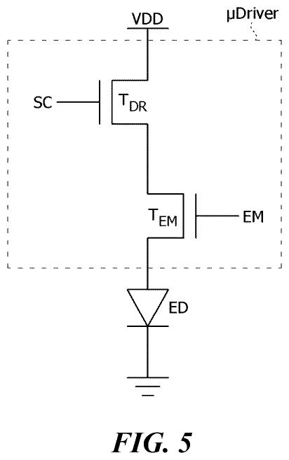

FIG. 5 is a view illustrating a circuit structure according to an embodiment of the present specification.

Although FIG. 5 shows that a single light emitting diode ED is connected to a micro driver μ-Driver, the present specification is not limited thereto. For example, eight light emitting diodes ED may be connected to a single micro driver (μ-Driver). In another example, sixteen light emitting diodes ED may be connected to a single micro driver μ-Driver, or thirty-two light emitting diodes ED or sixty-four light emitting diodes ED may be simultaneously connected to a single micro driver μ-Driver. The light emitting diodes ED may be micro light emitting diodes (μ-LEDs).

A single micro driver μ-Driver may include a driving transistor T_{DR} and a light emitting transistor T_{EM}, but the embodiments of the present specification are not limited thereto.

For example, the driving transistor T_{DR} may have a first electrode to which a high-potential power voltage VDD is applied, a second electrode connected to a first electrode of the light emitting transistor T_{EM}, and a gate electrode to which a scan signal SC is applied. The scan signal SC applied to the gate electrode of the driving transistor T_{DR} may be direct current power, and a fixed reference voltage Vref may be applied every frame, but the embodiments of the present specification are not limited thereto.

The light emitting transistor T_{EM} may have the first electrode to which the second electrode of the driving transistor T_{DR} is connected, a second electrode to which the light emitting diode ED is connected, and a gate electrode to which a light emitting signal EM is applied. The light emitting signal EM applied to the gate electrode of the light emitting transistor T_{EM} may be a pulse width modulation signal that changes every frame, but the embodiments of the present specification are not limited thereto.

A first electrode of the light emitting diode ED may be connected to the second electrode of the light emitting transistor T_{EM}, and a second electrode of the light emitting diode ED may be connected to a ground. For example, the first electrode of the light emitting diode ED may be an anode electrode, and the second electrode of the light emitting diode ED may be a cathode electrode, but the embodiments of the present specification are not limited thereto.

The driving transistor T_{DR} and the light emitting transistor T_{EM} may each be an n-type transistor or a p-type transistor.

In the micro driver (μ-Driver), the driving transistor T_{DR} may be turned on due to the scan signal SC applied from a timing controller T-CON, and the light emitting transistor T_{EM} may be turned on due to the light emitting signal EM. By this, the light emitting diode ED may emit light as driving current is applied to the light emitting diode ED via the driving transistor T_{DR} and the light emitting transistor T_{EM} due to the high-potential power voltage VDD applied to the first electrode of the driving transistor T_{DR}.

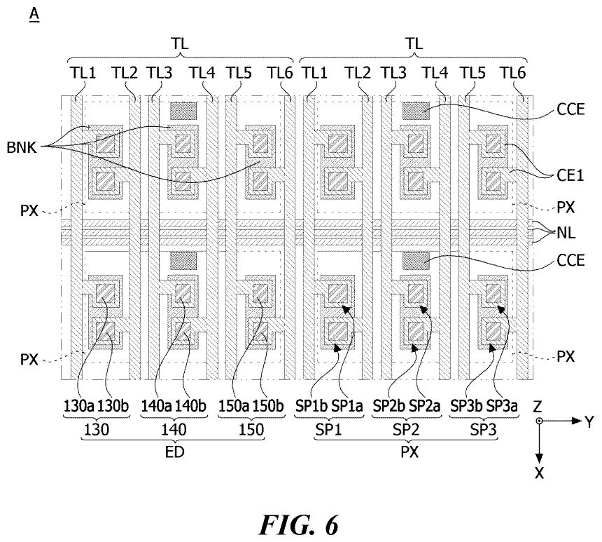

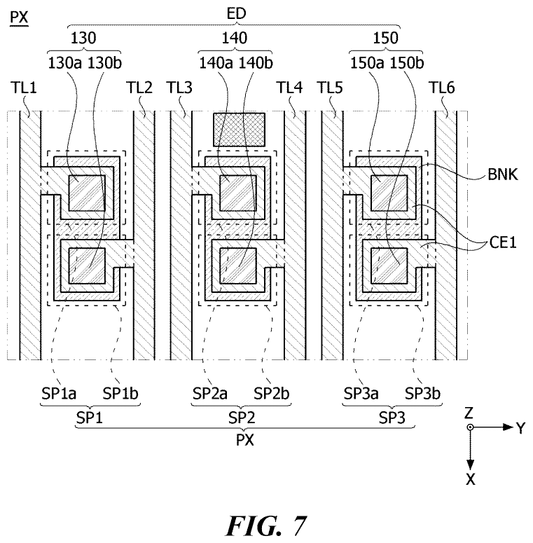

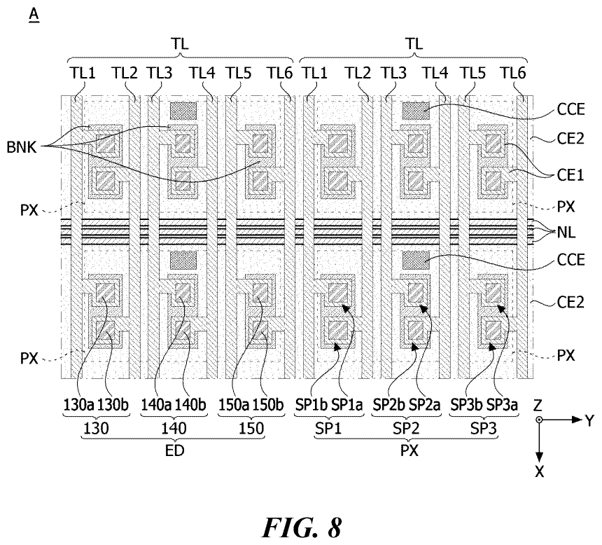

FIG. 6 is an enlarged view of a display area including a plurality of pixels. FIGS. 6 and 8 are partially enlarged views showing portion A of FIG. 3 in an enlarged manner. FIG. 7 is an enlarged view of a display area including a single pixel of FIG. 6.

Although only a plurality of signal lines TL, a plurality of communication lines NL, a plurality of first electrodes CE1, a plurality of banks BNK, and a plurality of light emitting diodes ED are illustrated in FIGS. 6 and 8, the embodiments of the present specification are not limited thereto. FIG. 8 is an enlarged plan view resulting from additionally placing a plurality of second electrodes CE2 in FIG. 6.

Referring to FIGS. 6 and 8, a plurality of pixels PX each including a plurality of subpixels may be disposed in a display area AA. The plurality of subpixels may each include a light emitting diode ED and may independently emit light. The plurality of subpixels may be arranged in a matrix form while forming a plurality of rows and a plurality of columns, but the embodiments of the present specification are not limited thereto.

The plurality of subpixels may include a first subpixel SP1, a second subpixel SP2, and a third subpixel SP3. For example, any one of the first subpixel SP1, the second subpixel SP2, and the third subpixel SP3 may be a red subpixel, another one may be a green subpixel, and the remaining one may be a blue subpixel. The types of the plurality of subpixels are only illustrative, and the embodiments of the present specification are not limited thereto.

The plurality of pixels PX may each include one or more first subpixels SP1, one or more second subpixels SP2, and one or more third subpixels SP3. For example, a single pixel PX may include a pair of first subpixels SP1, a pair of second subpixels SP2, and a pair of third subpixels SP3. The pair of first subpixels SP1 may consist of a (1-1)-th subpixel SP1a and a (1-2)-th subpixel SP1b. The pair of second subpixels SP2 may consist of a (2-1)-th subpixel SP2a and a (2-2)-th subpixel SP2b. The pair of third subpixels SP3 may consist of a (3-1)-th subpixel SP3a and a (3-2)-th subpixel SP3b. For example, a single pixel PX may include the (1-1)-th subpixel SP1a, the (1-2)-th subpixel SP1b, the (2-1)-th subpixel SP2a, the (2-2)-th subpixel SP2b, the (3-1)-th subpixel SP3a, and the (3-2)-th subpixel SP3b, but the embodiments of the present specification are not limited thereto.

A plurality of subpixels constituting a single pixel PX may be arranged in various ways. For example, in a single pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number and arrangement of a plurality of subpixels constituting a single pixel PX are only illustrative, and the embodiments of the present specification are not limited thereto.

The plurality of signal lines TL may be disposed in an area between a plurality of subpixels. The plurality of signal lines TL may extend in a column direction between the plurality of subpixels. The plurality of signal lines TL may be lines that transmit an anode voltage from the pixel driving circuit PD to the plurality of subpixels. For example, the plurality of signal lines TL may be electrically connected to the plurality of pixel driving circuits PD and the first electrodes CE1 of the plurality of subpixels. The anode voltage output from the pixel driving circuit PD may be transmitted to the first electrodes CE1 of the plurality of subpixels through the plurality of signal lines TL. For example, the first electrode CE1 may be an electrode electrically connected to an anode electrode 134 of the light emitting diode ED. Thus, the anode voltage from the signal line TL may be transmitted to the anode electrode 134 of the light emitting diode ED through the first electrode CE1.

Accordingly, instead of forming a plurality of transistors and a storage capacitor in each of the plurality of subpixels, the pixel driving circuit PD in which a plurality of pixel circuits are integrated may be used to simplify the structure of the display device 1000. In addition, since circuits each disposed in one of the plurality of subpixels are integrated in a single pixel driving circuit PD, high efficiency low-power driving may be possible. The circuits each disposed in one of the plurality of subpixels SP being integrated in a single pixel driving circuit PD may mean that the plurality of pixel circuits that can drive the plurality of light emitting diodes ED are included in the pixel driving circuit PD. The plurality of light emitting diodes ED may be driven by the single pixel driving circuit PD in which the plurality of pixel circuits are integrated. For example, a (1-1)-th light emitting diode 130a, a (2-1)-th light emitting diode 140a, and a (3-1)-th light emitting diode 150a may be driven by the single pixel driving circuit PD in which the plurality of pixel circuits are integrated.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may each be electrically connected to one of the pair of first subpixels SP1. The third signal line TL3 and the fourth signal line TL4 may each be electrically connected to one of the pair of second subpixels SP2. The fifth signal line TL5 and the sixth signal line TL6 may each be electrically connected to one of the pair of third subpixels SP3.

The first signal line TL1 may be disposed on one side of the pair of first subpixels SP1, and the second signal line TL2 may be disposed on the other side of the pair of first subpixels SP1. The first signal line TL1 may be electrically connected to the first electrode CE1 of one first subpixel SP1, e.g., the (1-1)-th subpixel SP1a, among the pair of first subpixels SP1. The second signal line TL2 may be electrically connected to the first electrode CE1 of the other first subpixel SP1, e.g., the (1-2)-th subpixel SP1b, among the pair of first subpixels SP1.

The third signal line TL3 may be disposed on one side of the pair of second subpixels SP2, and the fourth signal line TL4 may be disposed on the other side of the pair of second subpixels SP2. For example, the third signal line TL3 may be disposed to neighbor the second signal line TL2. The third signal line TL3 may be electrically connected to the first electrode CE1 of one second subpixel SP2, e.g., the (2-1)-th subpixel SP2a, among the pair of second subpixels SP2. The fourth signal line TL4 may be electrically connected to the first electrode CE1 of the other second subpixel SP2, e.g., the (2-2)-th subpixel SP2b, among the pair of second subpixels SP2.

The fifth signal line TL5 may be disposed on one side of the pair of third subpixels SP3, and the sixth signal line TL6 may be disposed on the other side of the pair of third subpixels SP3. For example, the fifth signal line TL5 may be disposed to neighbor the fourth signal line TL4. The sixth signal line TL6 may be disposed to neighbor the first signal line TL1 connected to a neighboring pixel PX. The fifth signal line TL5 may be electrically connected to the first electrode CE1 of one third subpixel SP3, e.g., the (3-1)-th subpixel SP3a, among the pair of third subpixels SP3. The sixth signal line TL6 may be electrically connected to the first electrode CE1 of the other third subpixel SP3, e.g., the (3-2)-th subpixel SP3b, among the pair of third subpixels SP3.

The plurality of signal lines TL may be made of a conductive material. For example, the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), and indium gallium zinc oxide (IGZO), but the embodiments of the present specification are not limited thereto. In another example, the plurality of signal lines TL may be made of a multilayer structure of conductive materials. For example, the plurality of signal lines TL may be made of a multilayer structure of titanium (Ti)/aluminum (Al)/titanium (Ti)/indium tin oxide (ITO), but the embodiments of the present specification are not limited thereto.

The plurality of communication lines NL may be disposed in an area between the plurality of pixels PX. The plurality of communication lines NL may be disposed to extend in a row direction in the area between the plurality of pixels PX. The plurality of communication lines NL may be disposed in an area between the plurality of second electrodes CE2 and may not overlap the plurality of second electrodes CE2. For example, the plurality of communication lines NL may be lines used for short-range communication such as near field communication (NFC). The plurality of communication lines NL may serve as antennas. For example, the plurality of communication lines NL may be a plurality of driving lines or the like, but the embodiments of the present specification are not limited thereto.

According to the present specification, a bank BNK may be disposed on each of the plurality of subpixels. The plurality of banks BNK may be structures on which the plurality of light emitting diodes ED are seated. The plurality of banks BNK may guide positions of the plurality of light emitting diodes ED in a transfer process for transferring the plurality of light emitting diodes ED to the display device 1000. The plurality of light emitting diodes ED may be transferred onto the plurality of banks BNK in the process of transferring the plurality of light emitting diodes ED. The plurality of banks BNK may be bank patterns or structures, but the embodiments of the present specification are not limited thereto.

The banks BNK of the first subpixels SP1, the banks BNK of the second subpixels SP2, and the banks BNK of the third subpixels SP3 may be disposed to be spaced from each other. The banks BNK of the first subpixels SP1, the banks BNK of the second subpixels SP2, and the banks BNK of the third subpixels SP3 may be configured to be separated. Thus, the banks BNK of the first subpixels SP1, the second subpixels SP2, and the third subpixels SP3 to which different types of light emitting diodes ED are transferred may be easily identified.

The bank BNK of the (1-1)-th subpixel SP1a and the bank BNK of the (1-2)-th subpixel SP1b may be connected to each other or may be formed to be spaced or separated from each other. For example, the bank BNK of the (1-1)-th subpixel SP1a and the bank BNK of the (1-2)-th subpixel SP1b on which the light emitting diodes ED of the same type are disposed in consideration of design such as transfer process requirements may be connected to each other or may be spaced or separated from each other. In addition, the bank BNK of the (2-1)-th subpixel SP2a and the bank BNK of the (2-2)-th subpixel SP2b may be connected to each other or may be formed to be spaced or separated from each other. The bank BNK of the (3-1)-th subpixel SP3a and the bank BNK of the (3-2)-th subpixel SP3b may be connected to each other or may be formed to be spaced or separated from each other. Therefore, the banks BNK of one pair of first subpixels SP1, the banks BNK of one pair of second subpixels SP2, and the banks BNK of one pair of third subpixels SP3 may be formed in various ways, but the embodiments of the present specification are not limited thereto.

For example, the plurality of banks BNK may be made of an organic insulating material. The plurality of banks BNK may be made of a single layer or multiple layers of an organic insulating material. For example, the plurality of banks BNK may be made of photoresist, polyimide (PI), or an acryl-based material, but the embodiments of the present specification are not limited thereto.

The first electrode CE1 may be disposed on each of the plurality of subpixels. The first electrode CE1 may be disposed on the bank BNK. The first electrode CE1 may be electrically connected to one signal line TL among the plurality of signal lines TL. At least one portion of the first electrode CE1 may extend to an outer side of the bank BNK and may be electrically connected to the signal line TL most adjacent to the first electrode CE1. For example, one portion of the first electrode CE1 of the (1-1)-th subpixel SP1a may extend to one side area of the (1-1)-th subpixel SP1a and may be electrically connected to the first signal line TL1, and one portion of the first electrode CE1 of the (1-2)-th subpixel SP1b may extend to the other side area of the (1-2)-th subpixel SP1b and may be electrically connected to the second signal line TL2. One portion of the first electrode CE1 of the (2-1)-th subpixel SP2a may extend to one side area of the (2-1)-th subpixel SP2a and may be electrically connected to the third signal line TL3, and one portion of the first electrode CE1 of the (2-2)-th subpixel SP2b may extend to the other side area of the (2-2)-th subpixel SP2b and may be electrically connected to the fourth signal line TL4. One portion of the first electrode CE1 of the (3-1)-th subpixel SP3a may extend to one side area of the (3-1)-th subpixel SP3a and may be electrically connected to the fifth signal line TL5, and one portion of the first electrode CE1 of the (3-2)-th subpixel SP3b may extend to the other side area of the (3-2)-th subpixel SP3b and may be electrically connected to the sixth signal line TL6.

The first electrode CE1 may be electrically connected to the anode electrode 134 of the light emitting diode ED and may transmit the anode voltage from the pixel driving circuit PD to the light emitting diode ED through the signal line TL. Different voltages may be applied to the first electrode CE1 of each of the plurality of subpixels according to an image being displayed. For example, voltages different from each other may be applied to the first electrode CE1 of each of the plurality of subpixels. Thus, the first electrode CE1 may be a pixel electrode, but the embodiments of the present specification are not limited thereto.

The first electrode CE1 may be made of a conductive material. For example, the first electrode CE1 may be integrally configured with the plurality of signal lines TL. For example, the first electrode CE1 may be made of the same conductive material as the plurality of signal lines TL, but the embodiments of the present specification are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), and indium gallium zinc oxide (IGZO), but the embodiments of the present specification are not limited thereto. In another example, the first electrode CE1 may be made of a multilayer structure of conductive materials. For example, the plurality of first electrodes CE1 may be made of a multilayer structure of titanium (Ti)/aluminum (Al)/titanium (Ti)/indium tin oxide (ITO), but the embodiments of the present specification are not limited thereto.

The light emitting diode ED may be disposed on each of the plurality of subpixels. The plurality of light emitting diodes ED may be any one of light-emitting diodes (LEDs) or micro light-emitting diodes (micro LEDs), but the embodiments of the present specification are not limited thereto. The plurality of light emitting diodes ED may be disposed on the bank BNK and the first electrode CE1. The plurality of light emitting diodes ED may be disposed on the first electrode CE1 and may be electrically connected to the first electrode CE1. Therefore, the light emitting diode ED may emit light by receiving the anode voltage from the pixel driving circuit PD through the signal line TL and the first electrode CE1.

The plurality of light emitting diodes ED may include a first light emitting diode 130, a second light emitting diode 140, and a third light emitting diode 150. The first light emitting diode 130 may be disposed on the first subpixel SP1. The second light emitting diode 140 may be disposed on the second subpixel SP2. The third light emitting diode 150 may be disposed on the third subpixel SP3. For example, any one of the first light emitting diode 130, the second light emitting diode 140, and the third light emitting diode 150 may be a red light emitting diode, another one may be a green light emitting diode, and the remaining one may be a blue light emitting diode, but the embodiments of the present specification are not limited thereto. Thus, red light, green light, and blue light emitted from the plurality of light emitting diodes ED may be combined to implement lights of various colors including white light. The types of the plurality of light emitting diodes ED are only illustrative, and the embodiments of the present specification are not limited thereto.

The first light emitting diode 130 may include the (1-1)-th light emitting diode 130a disposed on the (1-1)-th subpixel SP1a and a (1-2)-th light emitting diode 130b disposed on the (1-2)-th subpixel SP1b. The second light emitting diode 140 may include the (2-1)-th light emitting diode 140a disposed on the (2-1)-th subpixel SP2a and a (2-2)-th light emitting diode 140b disposed on the (2-2)-th subpixel SP2b. The third light emitting diode 150 may include the (3-1)-th light emitting diode 150a disposed on the (3-1)-th subpixel SP3a and a (3-2)-th light emitting diode 150b disposed on the (3-2)-th subpixel SP3b.

Referring to FIGS. 6 and 8, the second electrode CE2 may be disposed on each of the plurality of subpixels. The second electrode CE2 may be disposed on the light emitting diode ED. The second electrode CE2 may be electrically connected to the pixel driving circuit PD through a plurality of contact electrodes CCE.

For example, the second electrode CE2 may be electrically connected to a cathode electrode 135 of the light emitting diode ED and may transmit a cathode voltage from the pixel driving circuit PD to the light emitting diode ED. The same cathode voltage may be applied to the second electrode CE2 of each of the plurality of subpixels. For example, the same voltage may be applied to the second electrode CE2 of each of the plurality of subpixels and the cathode electrode 135 of the light emitting diode ED. Thus, the second electrode CE2 may be a common electrode, but the embodiments of the present specification are not limited thereto.

At least some of the plurality of subpixels may share the second electrode CE2. At least some of the second electrodes CE2 of the plurality of subpixels may be electrically connected to each other. As the same voltage is applied to the second electrodes CE2, the second electrodes CE2 of at least some of the subpixels may be shared and used. For example, the second electrodes CE2 of at least some pixels PX among the plurality of pixels PX disposed in the same row may be connected to each other. For example, a single second electrode CE2 may be disposed on the plurality of pixels PX. A single second electrode CE2 may be disposed for every n subpixels.

For example, some of the second electrodes CE2 of the plurality of subpixels may be disposed to be spaced or separated from each other. For example, the second electrode CE2 connected to pixels PX of an n^{th} row and the second electrode CE2 connected to pixels PX of an (n+1)^{th} row may be disposed to be spaced or separated from each other. For example, the plurality of second electrodes CE2 may be disposed to be spaced from each other with the plurality of communication lines NL, which extend in the row direction, disposed therebetween. Thus, the number of the plurality of subpixels may be greater than the number of the plurality of second electrodes CE2. In another example, all of the second electrodes CE2 of the plurality of subpixels may be connected to each other and only one second electrode CE2 may be disposed on the substrate 110, but the embodiments of the present specification are not limited thereto.

The plurality of second electrodes CE2 may be made of a transparent conductive material, but the embodiments of the present specification are not limited thereto. The plurality of second electrodes CE2 may be made of a transparent conductive material so that light emitted from the light emitting diode ED is directed toward an upper portion of the second electrode C2. For example, the second electrode CE2 may be made of a transparent conductive material such as indium tin oxide (ITO), indium zinc oxide (IZO), and indium gallium zinc oxide (IGZO), but the embodiments of the present specification are not limited thereto.

The plurality of contact electrodes CCE may be disposed on the substrate 110. For example, the plurality of contact electrodes CCE may be disposed to be spaced from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 and may transmit a cathode voltage from the pixel driving circuit PD to the second electrode CE2.

For example, in a case in which a micro LED is used as the light emitting diode ED, a plurality of micro LEDs may be formed on a wafer, and the micro LEDs may be transferred to the substrate 110 of the display device 1000 to manufacture the display device 1000. Various defects may occur in a process of transferring the plurality of light emitting diodes ED having a fine size from the wafer to the substrate 110. For example, a non-transfer defect in which the light emitting diode ED is not transferred may occur in some subpixels, and a defect in which the light emitting diode ED is transferred while deviating from its correct position due to an alignment error may occur in some other subpixels. In addition, even when the transfer process is normally performed, the transferred light emitting diode ED itself may be defective. Therefore, during the process of transferring the plurality of light emitting diodes ED, in consideration of the defects, a plurality of light emitting diodes ED of the same type may be transferred to a single subpixel. A lighting test of the plurality of light emitting diodes ED may be performed, and only one light emitting diode ED that is judged normal may be finally used.

For example, the (1-1)-th light emitting diode 130a and the (1-2)-th light emitting diode 130b may be transferred together to a single pixel PX, and whether there are defects may be tested. If both the (1-1)-th light emitting diode 130a and the (1-2)-th light emitting diode 130b are judged normal, only the (1-1)-th light emitting diode 130a may be used, and the (1-2)-th light emitting diode 130b may not be used. In another example, if only the (1-2)-th light emitting diode 130b is judged normal among the (1-1)-th light emitting diode 130a and the (1-2)-th light emitting diode 130b, the (1-1)-th light emitting diode 130a may not be used, and only the (1-2)-th light emitting diode 130b may be used. Therefore, even when a plurality of light emitting diodes ED of the same type are transferred to a single pixel PX, only one light emitting diode ED may be finally used.

Thus, any one of the pair of light emitting diodes ED may be a main or primary light emitting diode ED, and the other may be a redundancy light emitting diode ED. The redundancy light emitting diode ED may be an extra light emitting diode ED transferred in preparation for a defect of the main light emitting diode ED. When a defect occurs in the main light emitting diode ED, the redundancy light emitting diode ED may be used instead. Therefore, by transferring the main light emitting diode ED and the redundancy light emitting diode ED together to a single pixel PX, a decrease in display quality due to defects of the main light emitting diode ED and the redundancy light emitting diode ED can be minimized.

For example, the (1-1)-th light emitting diode 130a, the (2-1)-th light emitting diode 140a, and the (3-1)-th light emitting diode 150a transferred to a single pixel PX may be used as main light emitting diodes ED, and the (1-2)-th light emitting diode 130b, the (2-2)-th light emitting diode 140b, and the (3-2)-th light emitting diode 150b may be used as redundancy light emitting diodes ED.

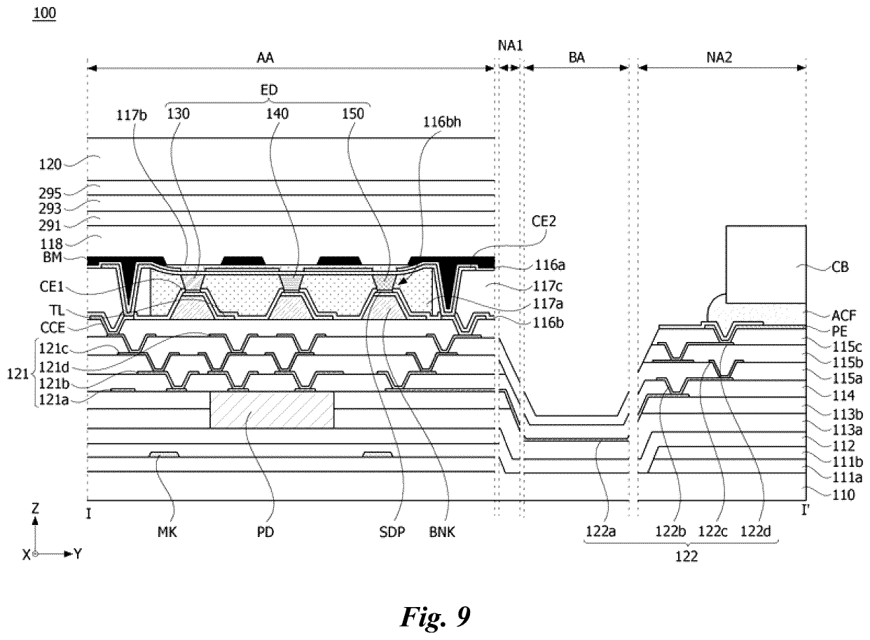

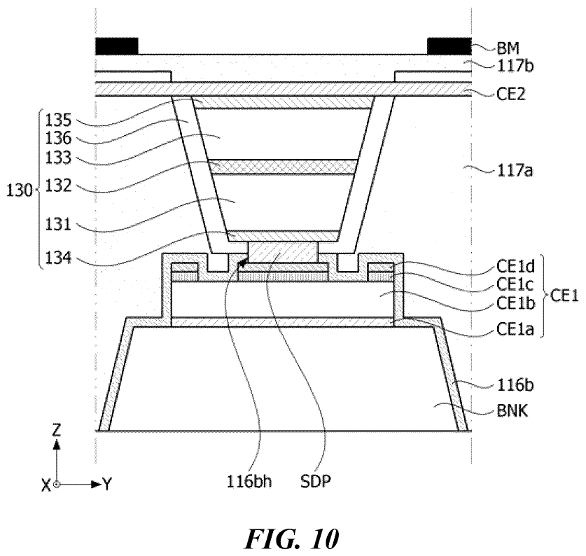

FIG. 9 is a cross-sectional view of the display device according to an embodiment of the present specification that is along line I-I′ of FIG. 4. FIG. 10 is a cross-sectional view illustrating a subpixel including a light emitting diode disposed in a display area AA.

FIG. 9 is a cross-sectional area of the display area AA, the first non-display area NA1, the bending area BA, and the second non-display area NA2.

FIG. 9 is a cross-sectional view illustrating the display device according to an embodiment of the present specification.

Referring to FIG. 9, a circuit layer may be disposed on the substrate 110.

The circuit layer may include first to third protective layers 113a, 113b, and 114 and first to third insulating layers 115a, 115b, and 115c. The pixel driving circuit PD and a plurality of driving lines 121 and 122 may be disposed on the circuit layer for driving of the display device. The pixel driving circuit PD and the plurality of driving lines 121 and 122 may be electrically connected through a contact hole disposed in the first to third protective layers 113a, 113b, and 114 and the first to third insulating layers 115a, 115b, and 115c.

The connection structure and arrangement of the pixel driving circuit PD, the plurality of driving lines 121 and 122, the first to third protective layers 113a, 113b, and 114, and the first to third insulating layers 115a, 115b, and 115c will be described in detail below.

A first buffer layer 111a and a second buffer layer 111b may be disposed in the remaining area of the substrate 110 excluding the bending area BA.

The first buffer layer 111a and the second buffer layer 111b may be disposed in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be made of an inorganic insulating material. For example, the first buffer layer 111a and the second buffer layer 111b may be made of a single layer or multiple layers of silicon oxide (SiOx) or silicon nitride (SiNx), but the embodiments of the present specification are not limited thereto.

For example, portions of the first buffer layer 111a and the second buffer layer 111b present in the bending area BA may be removed. An upper surface of the substrate 110 located in the bending area BA may be exposed from the first buffer layer 111a and the second buffer layer 111b. By removing the first buffer layer 111a and the second buffer layer 111b made of an inorganic insulating material from the bending area BA, it is possible to minimize cracks in the first buffer layer 111a and the second buffer layer 111b that may occur at the time of bending.

A plurality of align keys MK may be disposed between the first buffer layer 111a and the second buffer layer 111b. The plurality of align keys MK may be configured to identify the position of the pixel driving circuit PD during the process of manufacturing the display device 1000. For example, the plurality of align keys MK may be configured to align the position of the pixel driving circuit PD transferred onto an adhesive layer 112. In another example, the plurality of align keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least one portion of the adhesive layer 112 may be removed from the non-display area NA including the bending area BA. For example, the adhesive layer 112 may be made of any one of an adhesive polymer, an epoxy resin, a UV curable resin, a polyimide-based material, an acrylate-based material, a urethane-based material, and polydimethylsiloxane (PDMS), but the embodiments of the present specification are not limited thereto.

In the display area AA, the pixel driving circuit PD may be disposed on the adhesive layer 112. When the pixel driving circuit PD is implemented as a driver, the driver may be mounted on the adhesive layer 112 by a transfer process, but the embodiments of the present specification are not limited thereto.

A first protective layer 113a and a second protective layer 113b may be disposed on the adhesive layer 112. The first protective layer 113a and the second protective layer 113b may be disposed to surround a side surface of the pixel driving circuit PD, but the embodiments of the present specification are not limited thereto. For example, the second protective layer 113b may be disposed to cover at least one portion of an upper surface of the pixel driving circuit PD. For example, at least one of the first protective layer 113a and the second protective layer 113b disposed in the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, one portion of the second protective layer 113b present in the bending area BA may be removed. However, the embodiments of the present specification are not limited thereto.

The first protective layer 113a and the second protective layer 113b may be made of an organic insulating material, but the embodiments of the present specification are not limited thereto. For example, the first protective layer 113a and the second protective layer 113b may be made of photoresist, polyimide (PI), or a photo acryl-based material, but the embodiments of the present specification are not limited thereto. For example, the first protective layer 113a and the second protective layer 113b may be overcoating layers or insulating layers, but the embodiments of the present specification are not limited thereto.

According to the present specification, a plurality of first driving lines 121 may be disposed on the second protective layer 113b in the display area AA. The plurality of first driving lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first driving lines 121. For example, the plurality of first driving lines 121 may include a (1-1)-th driving line 121a, a (1-2)-th driving line 121b, a (1-3)-th driving line 121c, and a (1-4)-th driving line 121d, but the embodiments of the present specification are not limited thereto.

For example, a plurality of (1-1)-th driving lines 121a may be disposed on the second protective layer 113b. The plurality of (1-1)-th driving lines 121a may be electrically connected to the pixel driving circuit PD. The plurality of (1-1)-th driving lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be made of an organic insulating material. For example, the third protective layer 114 may be made of photoresist, polyimide (PI), or a photo acryl-based material, but the embodiments of the present specification are not limited thereto. For example, the first protective layer 113a, the second protective layer 113b, and the third protective layer 114 may be made of the same material, but the embodiments of the present specification are not limited thereto.

A plurality of (1-2)-th driving lines 121b may be disposed on the third protective layer 114. The plurality of (1-2)-th driving lines 121b may be connected or directly connected to the pixel driving circuit PD. For example, some of the (1-2)-th driving lines 121b may be directly connected to the pixel driving circuit PD through a contact hole of the third protective layer 114. The rest of the (1-2)-th driving lines 121b may be electrically connected to the (1-1)-th driving line 121a through the contact hole of the third protective layer 114. However, the embodiments of the present specification are not limited thereto. A voltage output from the pixel driving circuit PD may be transmitted to the first electrode CE1 or the second electrode CE2 through the plurality of (1-2)-th driving lines 121b and other driving lines.

A first insulating layer 115a may be disposed on the plurality of (1-2)-th driving lines 121b. The first insulating layer 115a may be entirely disposed in the display area AA and the non-display area NA, but the embodiments of the present specification are not limited thereto. The first insulating layer 115a may be made of an organic insulating material, but the embodiments of the present specification are not limited thereto. For example, the first insulating layer 115a may be made of photoresist, polyimide (PI), or a photo acryl-based material, but the embodiments of the present specification are not limited thereto.

A plurality of (1-3)-th driving lines 121c may be disposed on the first insulating layer 115a. The plurality of (1-3)-th driving lines 121c may be electrically connected to the plurality of (1-2)-th driving lines 121b. For example, the (1-3)-th driving line 121c may be electrically connected to the (1-2)-th driving line 121b through a contact hole of the first insulating layer 115a.

A second insulating layer 115b may be disposed on the plurality of (1-3)-th driving lines 121c. The second insulating layer 115b may be disposed in the remaining area excluding the bending area BA, but the embodiments of the present specification are not limited thereto. The second insulating layer 115b may be disposed in the display area AA, the first non-display area NA1, and the second non-display area NA2, but the embodiments of the present specification are not limited thereto. For example, one portion of the second insulating layer 115b disposed in the bending area BA may be removed. The second insulating layer 115b may be made of an organic insulating material, but the embodiments of the present specification are not limited thereto. For example, the second insulating layer 115b may be made of photoresist, polyimide (PI), or a photo acryl-based material, but the embodiments of the present specification are not limited thereto.

A plurality of (1-4)-th driving lines 121d may be disposed on the second insulating layer 115b. The plurality of (1-4)-th driving lines 121d may be electrically connected to the plurality of (1-3)-th driving lines 121c. For example, the (1-4)-th driving line 121d may be electrically connected to the (1-3)-th driving line 121c through a contact hole of the second insulating layer 115b.

According to the present specification, in the non-display area NA, a plurality of second driving lines 122 may be disposed on the second protective layer 113b. The plurality of second driving lines 122 may be lines for transmitting a signal, which is transmitted from the flexible circuit board (or flexible film) CB and the printed circuit board 160 (see FIG. 1) to the pad portion PAD, to the pixel driving circuit PD of the display area AA. For example, the plurality of second driving lines 122 may be electrically connected to the plurality of pad electrodes PE and may receive a signal from the flexible circuit board (or flexible film) CB and the printed circuit board.

For example, the plurality of second driving lines 122 may extend from the pad portion PAD toward the display area AA and may transmit a signal to a line of the display area AA. In this case, the plurality of second driving lines 122 may serve as link lines LL. The plurality of second driving lines 122 may include a (2-1)-th driving line 122a, a (2-2)-th driving line 122b, a (2-3)-th driving line 122c, and a (2-4)-th driving line 122d.

A plurality of (2-1)-th driving lines 122a may be disposed on the second protective layer 113b. The plurality of (2-1)-th driving lines 122a may extend from the second non-display are NA2 to the bending area BA and the first non-display area NA1. The plurality of (2-1)-th driving lines 122a may transmit a signal, which is transmitted from the flexible circuit board (or flexible film) CB and the printed circuit board to the pad portion PAD, to the pixel driving circuit PD of the display area AA.

A plurality of (2-2)-th driving lines 122b may be disposed on the third protective layer 114. The plurality of (2-2)-th driving lines 122b may be disposed in the second non-display area NA2. The (2-2)-th driving line 122b may be electrically connected to the (2-1)-th driving line 122a through a contact hole of the third protective layer 114. Therefore, a signal from the flexible circuit board (or flexible film) CB and the printed circuit board can be transmitted to the (2-1)-th driving line 122a through the (2-2)-th driving line 122b.

The (2-3)-th driving line 122c may be disposed on the first insulating layer 115a. The (2-3)-th driving line 122c may be disposed in the second non-display area NA2. The (2-3)-th driving line 122c may be electrically connected to the (2-2)-th driving line 122b through a contact hole of the first insulating layer 115a. Therefore, a signal from the flexible circuit board (or flexible film) CB and the printed circuit board can be transmitted to the (2-1)-th driving line 122a through the (2-3)-th driving line 122c and the (2-2)-th driving line 122b.

The (2-4)-th driving line 122d may be disposed on the second insulating layer 115b. The (2-4)-th driving line 122d may be disposed in the second non-display area NA2. The (2-4)-th driving line 122d may be electrically connected to the (2-3)-th driving line 122c through a contact hole of the second insulating layer 115b. Therefore, a signal from a flexible film FF and a printed circuit board can be transmitted to the (2-1)-th driving line 122a through the (2-4)-th driving line 122d, the (2-3)-th driving line 122c, and the (2-2)-th driving line 122b.

The plurality of first driving lines 121 and the plurality of second driving lines 122 may be formed of a conductive material with excellent flexibility or any one of various conductive materials used in the display area AA. For example, the second driving line 122 disposed on one portion of the bending area BA may be made of a conductive material with excellent flexibility such as gold (Au), silver (Ag), or aluminum (Al), but the embodiments of the present specification are not limited thereto. In another example, the plurality of first driving lines 121 and the plurality of second driving lines 122 may be made of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto.

A third insulating layer 115c may be disposed on the plurality of first driving lines 121 and the plurality of second driving lines 122. The third insulating layer 115c may be disposed in the remaining area excluding the bending area BA, but the embodiments of the present specification are not limited thereto. The third insulating layer 115c may be disposed in the display area AA, the first non-display area NA1, and the second non-display area NA2. One portion of the third insulating layer 115c present in the bending area BA may be removed. The third insulating layer 115c may be made of an organic insulating material, but the embodiments of the present specification are not limited thereto. For example, the third insulating layer 115c may be made of photoresist, polyimide (PI), or a photo acryl-based material, but the embodiments of the present specification are not limited thereto.

A plurality of banks BNK may be disposed on the third insulating layer 115c in the display area AA. The plurality of banks BNK may be disposed to each overlap one of the plurality of subpixels. One or more light emitting diodes ED of the same type may be disposed on an upper portion of each of the plurality of banks BNK.

The plurality of signal lines TL may be disposed on the third insulating layer 115c in the display area AA. The plurality of signal lines TL may be disposed in areas between the plurality of banks BNK. For example, the plurality of signal lines TL may be disposed adjacent to any one of the plurality of banks BNK.

The plurality of contact electrodes CCE may be disposed on the third insulating layer 115c in the display area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend from the signal line TL adjacent thereto toward an upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

A black matrix BM may be disposed on the second electrode CE2, a first optical layer 117a, a third optical layer 117c, and a second optical layer 117b in the display area AA. For example, the black matrix BM may fill a contact hole of the third optical layer 117c. Since the black matrix BM is configured to cover the display area AA, color mixture and external light reflection of light of the plurality of subpixels can be reduced. For example, since the black matrix BM is also disposed in a contact hole in which the second electrode CE2 and the contact electrode CCE are connected, light leakage between the plurality of subpixels neighboring each other can be prevented.

For example, the black matrix BM may be made of an opaque material, but the embodiments of the present specification are not limited thereto. For example, the black matrix BM may be an organic insulating material to which a black pigment or a black dye is added, but the embodiments of the present specification are not limited thereto.

A cover layer 118 may be disposed on the black matrix BM in the display area AA. The cover layer 118 may protect components under the cover layer 118. For example, the cover layer 118 may be made of an organic insulating material, but the embodiments of the present specification are not limited thereto. For example, the cover layer 118 may be made of photoresist, polyimide (PI), or a photo acryl-based material, but the embodiments of the present specification are not limited thereto. For example, the cover layer 118 may be an overcoating layer, an insulating layer, or the like, but the embodiments of the present specification are not limited thereto.

The polarizing layer 293 may be disposed on the cover layer 118 via a first adhesive layer 291. The cover member 120 may be disposed on the polarizing layer 293 via a second adhesive layer 295. For example, the first adhesive layer 291 and the second adhesive layer 295 may include an optically clear adhesive (OCA), an optically clear resin (OCR), a pressure sensitive adhesive (PSA), or the like, but the embodiments of the present specification are not limited thereto.

According to the present specification, the plurality of pad electrodes PE may be disposed on the third insulating layer 115c in the second non-display area NA2. For example, at least one portion of the plurality of pad electrodes PE may be exposed from a second passivation layer 116b. For example, the plurality of pad electrodes PE may be electrically connected to the (2-4)-th driving line 122d through a contact hole of the third insulating layer 115c.

An adhesive layer ACF may be disposed on the plurality of pad electrodes PE. The adhesive layer ACF may be an adhesive layer in which conductive balls are dispersed in an insulating material, but the embodiments of the present specification are not limited thereto. When heat or pressure is applied to the adhesive layer ACF, the conductive balls may be electrically connected and have a conductive characteristic at a portion to which heat or pressure is applied. The adhesive layer ACF may be disposed between the plurality of pad electrodes PE and the flexible circuit board (or flexible film) CB to attach or bond the flexible circuit board (or flexible film) CB to the plurality of pad electrodes PE. For example, the adhesive layer ACF may be an anisotropic conductive film (ACF), but the embodiments of the present specification are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Therefore, a signal output from the flexible circuit board (or flexible film) CB and the printed circuit board may be transmitted to the pixel driving circuit PD of the display area AA through the plurality of pad electrodes PE, the (2-4)-th driving line 122d, the (2-3)-th driving line 122c, the (2-2)-th driving line 122b, and the (2-1)-th driving line 122a.

FIG. 10 is a cross-sectional view illustrating a subpixel including a light emitting diode disposed in a display area AA.

Referring to FIG. 10, the first electrode CE1 may be made of a plurality of conductive layers. For example, the first electrode CE1 may include a first conductive layer CE1a, a second conductive layer CE1b, a third conductive layer CE1c, and a fourth conductive layer CE1d, but the embodiments of the present specification are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be made of titanium (Ti), molybdenum (Mo), aluminum (Al), or indium tin oxide (ITO), but the embodiments of the present specification are not limited thereto.

According to the present specification, some conductive layers with good reflection efficiency among the plurality of conductive layers constituting the first electrode CE1 may be configured as an align key and/or a reflector for aligning a light emitting diode ED. For example, the second conductive layer CE1b among the plurality of conductive layers of the first electrode CE1 may include a reflecting material. For example, the second conductive layer CE1b may include aluminum (Al), but the embodiments of the present specification are not limited thereto. Accordingly, the second conductive layer CE1b may be configured as a reflector. In addition, identification may be easy in the manufacturing process due to high reflection efficiency of the second conductive layer CE1b, and thus the position or transfer position of the light emitting diode ED may be aligned based on the second conductive layer CE1b.

For example, in order to configure the second conductive layer CE1b as a reflector, the third conductive layer CE1c and the fourth conductive layer CE1d covering the second conductive layer CE1b may be partially removed or etched. For example, an upper surface of the second conductive layer CE1b may be exposed by removing or etching one portion of the third conductive layer CE1c and the fourth conductive layer CE1d disposed on the bank BNK. For example, a central portion where a solder pattern SDP is disposed and an edge portion of the third conductive layer CE1c and the fourth conductive layer CE1d may be left, and the remaining portion excluding the central portion and the edge portion may be removed. For example, an edge portion of each of the third conductive layer CE1c made of titanium (Ti) and the fourth conductive layer CE1d made of indium tin oxide (ITO) may not be etched. Accordingly, corrosion of another conductive layer of the first electrode CE1 due to a tetramethylammonium hydroxide (TMAH) solution used in a process of masking the first electrode CE1 can be prevented.

According to the present specification, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) that has good adhesion to the solder pattern SDP and has corrosion resistance and acid resistance. However, the embodiments of the present specification are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present specification are not limited thereto.

According to the present specification, the signal line TL, the contact electrode CCE, and the pad electrode PE that are disposed on the same layer as the first electrode CE1 may be made of multiple layers of conductive materials, but the embodiments of the present specification are not limited thereto. For example, the signal line TL, the contact electrode CCE, and the pad electrode PE may be made of multiple layers of indium tin oxide (ITO)/titanium (Ti)/aluminum (Al)/titanium (Ti), but the embodiments of the present specification are not limited thereto.

According to the present specification, the solder pattern SDP may be disposed on the first electrode CE1 in each of the plurality of subpixels. The solder pattern SDP may bond the light emitting diode ED to the first electrode CE1. The first electrode CE1 and the light emitting diode ED may be electrically connected through eutectic bonding using the solder pattern SDP, but the embodiments of the present specification are not limited thereto. For example, if the solder pattern SDP is made of indium (In), and the anode electrode 134 of the light emitting diode ED is made of gold (Au), the solder pattern SDP and the anode electrode 134 may be bonded by applying heat and pressure in a process of transferring the light emitting diode ED. Through eutectic bonding, the light emitting diode ED may be bonded to the solder pattern SDP and the first electrode CE1 without a separate adhesive material. For example, the solder pattern SDP may be made of indium (In), tin (Sn), or an alloy thereof, but the embodiments of the present specification are not limited thereto. For example, the solder pattern SDP may be a bonding pad or the like, but the embodiments of the present specification are not limited thereto.

According to the present specification, the second passivation layer 116b may be disposed on the plurality of signal lines TL, the plurality of first electrodes CE1, the plurality of contact electrodes CCE, and the third insulating layer 115c. For example, the second passivation layer 116b may be disposed in the display area AA, the first non-display area NA1, and the second non-display area NA2. One portion of the second passivation layer 116b disposed in the bending area BA may be removed. One portion of the second passivation layer 116b covering the plurality of pad electrodes PE in the second non-display area NA2 may be removed. Since the second passivation layer 116b is disposed to cover the remaining area excluding the bending area BA, the plurality of pad electrodes PE, and the area in which the solder pattern SDP is disposed, penetration of moisture or impurities into the light emitting diode ED can be reduced. For example, the second passivation layer 116b may be made of a single layer or multiple layers of silicon oxide (SiOx) or silicon nitride (SiNx), but the embodiments of the present specification are not limited thereto. For example, the second passivation layer 116b may be a protective layer, an insulating layer, or the like, but the embodiments of the present specification are not limited thereto. For example, the second passivation layer 116b may include an opening 116bh through which the solder pattern SDP is exposed.

The light emitting diode ED may be disposed on the solder pattern SDP in each of the plurality of subpixels. The first light emitting diode 130 may be disposed on the first subpixel SP1. The second light emitting diode 140 may be disposed on the second subpixel SP2. The third light emitting diode 150 may be disposed on the third subpixel SP3.

The light emitting diode ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present specification are not limited thereto.

The first optical layer 117a surrounding the plurality of light emitting diodes ED may be disposed in the display area AA. For example, the first optical layer 117a may be disposed to cover a plurality of light emitting diodes ED and a bank BNK in areas of the plurality of subpixels. For example, the first optical layer 117a may cover a bank BNK, a portion of a second passivation layer 116b, and portions between a plurality of light emitting diodes ED. The first optical layer 117a may be disposed in or may cover portions between a plurality of light emitting diodes ED and between a plurality of banks BNK included in a single pixel PX. For example, the first optical layer 117a may be disposed to extend in the first direction X and be spaced in the second direction Y. For example, the first optical layer 117a may be disposed to surround side portions of the light emitting diodes ED and the banks BNK between the second passivation layer 116b and the second electrode CE2, but the embodiments of the present specification are not limited thereto. For example, the first optical layer 117a may be a diffusion layer, a sidewall diffusion layer, or the like, but the embodiments of the present specification are not limited thereto.

The first optical layer 117a may include an organic insulating material in which fine particles are dispersed, but the embodiments of the present specification are not limited thereto. For example, the first optical layer 117a may be made of siloxane in which fine metal particles such as titanium dioxide (TiO₂) particles are dispersed, but the embodiments of the present specification are not limited thereto. Light from the plurality of light emitting diodes ED may be scattered due to the fine particles dispersed in the first optical layer 117a and may be released to the outside of the display device 1000. Thus, the first optical layer 117a can improve extraction efficiency of light emitted from the plurality of light emitting diodes ED.

For example, the first optical layer 117a may be disposed on each of the plurality of pixels PX or may be disposed together on some pixels PX disposed in the same row, but the embodiments of the present specification are not limited thereto. For example, the first optical layer 117a may be disposed on each of the plurality of pixels PX, or the plurality of pixels PX may share one first optical layer 117a. In another example, the plurality of subpixels may each separately include the first optical layer 117a, but the embodiments of the present specification are not limited thereto.

According to the present specification, the third optical layer 117c may be disposed on the second passivation layer 116b in the display area AA. For example, the third optical layer 117c may be disposed to surround the first optical layer 117a. For example, the third optical layer 117c may abut a side surface of the first optical layer 117a. For example, the third optical layer 117c may be disposed in an area between a plurality of pixels PX. However, the embodiments of the present specification are not limited thereto. For example, the third optical layer 117c may be a diffusion layer, a diffusion layer window, a window diffusion layer, or the like, but the embodiments of the present specification are not limited thereto.

The third optical layer 117c may be made of an organic insulating material, but the embodiments of the present specification are not limited thereto. The third optical layer 117c may be made of the same material as the first optical layer 117a, but the embodiments of the present specification are not limited thereto. For example, the third optical layer 117c may not include fine particles while the first optical layer 117a includes fine particles. For example, the third optical layer 117c may be made of siloxane, but the embodiments of the present specification are not limited thereto.

For example, a thickness of the first optical layer 117a may be smaller than a thickness of the third optical layer 117c, but the embodiments of the present specification are not limited thereto. Accordingly, in a plan view, an area in which the first optical layer 117a is disposed may include a concave portion that is recessed inward as compared with an upper surface of the third optical layer 117c.

According to the present specification, the second electrode CE2 may be disposed on the first optical layer 117a and the third optical layer 117c. For example, the second electrode CE2 may be electrically connected to the plurality of contact electrodes CCE through a contact hole of the third optical layer 117c. For example, the second electrode CE2 may be disposed on the plurality of light emitting diodes ED. For example, the second electrode CE2 may include a transparent conductive oxide such as indium tin oxide (ITO) or indium zinc oxide (IZO), but the embodiments of the present specification are not limited thereto. For example, the second electrode CE2 may be disposed to come into contact with the cathode electrode 135. For example, the second electrode CE2 may overlap the first optical layer 117a. For example, the second electrode CE2 may cover a flat surface of an outer side of the first optical layer 117a.

The second electrode CE2 may continuously extend in the first direction X of the substrate 110. Accordingly, the second electrode CE2 may be connected in common to the plurality of pixels PX arranged in the first direction X of the substrate 110. For example, the second electrode CE2 may be connected in common to the plurality of pixels PX.

According to the present specification, the second electrode CE2 may continuously extend on the first optical layer 117a, the third optical layer 117c, and the light emitting diode ED. The area in which the first optical layer 117a is disposed may include a concave portion that is recessed inward as compared with the upper surface of the third optical layer 117c. Accordingly, since a first portion of the second electrode CE2 disposed on the first optical layer 117a is disposed along the concave portion, the first portion may be disposed at a lower position than a second portion of the second electrode CE2 disposed on the third optical layer 117c.

The second optical layer 117b may be disposed on the second electrode CE2. The second optical layer 117b may be disposed to overlap the plurality of light emitting diodes ED and the first optical layer 117a. Since the second optical layer 117b is disposed on upper portions of the second electrode CE2 and the plurality of light emitting diodes ED, mura that may occur in some of the plurality of light emitting diodes ED can be addressed. For example, when the plurality of light emitting diodes ED are transferred onto the substrate 110 of the display device 1000, an area in which gaps between the plurality of light emitting diodes ED are not uniform may be generated due to process variation or the like. When the gaps between the plurality of light emitting diodes ED are not uniform, a light output area of each of the plurality of light emitting diodes ED may be disposed in a non-uniform manner, and thus mura may be visible to a user. Accordingly, since the second optical layer 117b configured to uniformly diffuse light is disposed on upper portions of the plurality of light emitting diodes ED, a phenomenon in which light emitted from some of the light emitting diodes ED is viewed as mura can be reduced. Therefore, since the second optical layer 117b allows light emitted from the plurality of light emitting diodes ED to be evenly diffused and extracted to the outside of the display device 1000, brightness uniformity of the display device 1000 can be improved.

The second optical layer 117b may be made of an organic insulating material in which fine particles are dispersed, but the embodiments of the present specification are not limited thereto. For example, the second optical layer 117b may be made of siloxane in which fine metal particles such as titanium dioxide (TiO₂) particles are dispersed, but the embodiments of the present specification are not limited thereto. For example, the second optical layer 117b may be made of the same material as the first optical layer 117a, but the embodiments of the present specification are not limited thereto. For example, the second optical layer 117b may be a diffusion layer, an upper surface diffusion layer, or the like, but the embodiments of the present specification are not limited thereto.

According to the present specification, light from the plurality of light emitting diodes ED may be scattered due to the fine particles dispersed in the second optical layer 117b and may be released to the outside of the display device 1000. The second optical layer 117b may evenly mix light emitted from the plurality of light emitting diodes ED and may further improve brightness uniformity of the display device 1000. In addition, the light extraction efficiency of the display device 1000 can be improved by the light scattered from the plurality of fine particles, and thus the display device 1000 can operate with low power.

According to the present specification, a first passivation layer 116a may be disposed on the first optical layer 117a. Alternatively, the first passivation layer 116a may be disposed on the second optical layer 117b. Alternatively, the first passivation layer 116a may be disposed on the third optical layer 117c. For example, the first passivation layer 116a may be disposed in the display area AA and the first non-display area NA1. Since the first passivation layer 116a is disposed to cover the first optical layer 117a, the second optical layer 117b, or the third optical layer 117c disposed in the display area AA and the first non-display area NA1, penetration of moisture or impurities into the first optical layer 117a, the second optical layer 117b, or the third optical layer 117c can be reduced. For example, the first passivation layer 116a may be made of a single layer or multiple layers of silicon oxide (SiOx) or silicon nitride (SiNx), but the embodiments of the present specification are not limited thereto. For example, the first passivation layer 116a may be a transparent protective layer, an transparent insulating layer, or the like, but the embodiments of the present specification are not limited thereto.

The first light emitting diode 130 may include an anode electrode 134, a first semiconductor layer 131, an active layer 132, a second semiconductor layer 133, a cathode electrode 135, and an encapsulation layer 136, but the embodiments of the present specification are not limited thereto. For example, the encapsulation layer 136 may not be included in the first light emitting diode 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor such as a III-V compound semiconductor or a II-VI compound semiconductor and may be doped with impurities (or dopants). For example, one of the first semiconductor layer 131 and the second semiconductor layer 133 may be a semiconductor layer doped with n-type impurities, and the other may be a semiconductor layer doped with p-type impurities, but the embodiments of the present specification are not limited thereto. For example, one or more of the first semiconductor layer 131 and the second semiconductor layer 133 may be a layer in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs) is doped with n-type or p-type impurities, but the embodiments of the present specification are not limited thereto. For example, the n-type impurities may be silicon (Si), germanium (Ge), selenium (Sc), carbon (C), tellurium (Te), or tin (Sn), but the embodiments of the present specification are not limited thereto. For example, the p-type impurities may be magnesium (Mg), zinc (Zn), calcium (Ca), strontium (Sr), barium (Ba), or beryllium (Be), but the embodiments of the present specification are not limited thereto.

For example, the first semiconductor layer 131 and the second semiconductor layer 133 may be a nitride semiconductor including n-type impurities and a nitride semiconductor including p-type impurities, respectively, but the embodiments of the present specification are not limited thereto. For example, the first semiconductor layer 131 may be a nitride semiconductor including p-type impurities, and the second semiconductor layer 133 may be a nitride semiconductor including n-type impurities, but the embodiments of the present specification are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and may emit light. For example, the active layer 132 may be made of one of a single well structure, a multi-well structure, a single quantum well structure, a multi-quantum well (MQW) structure, a quantum dot structure, and a quantum wire structure, but the embodiments of the present specification are not limited thereto. For example, the active layer 132 may be made of indium gallium nitride (InGaN) or gallium nitride (GaN), but the embodiments of the present specification are not limited thereto.

In another example, the active layer 132 may include a multi-quantum well (MQW) structure having a well layer and a barrier layer with a higher band gap than the well layer. For example, the active layer 132 may be made of a well layer made of InGaN and a barrier layer made of an AlGaN layer, but the embodiments of the present specification are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be made of a conductive material capable of eutectic bonding with the solder pattern SDP, but the embodiments of the present specification are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present specification are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be made of a transparent conductive material so that light emitted from the light emitting diode ED is directed toward an upper portion of the light emitting diode ED, but the embodiments of the present specification are not limited thereto. For example, the cathode electrode 135 may be made of a material such as indium tin oxide (ITO), indium zinc oxide (IZO), or indium gallium zinc oxide (IGZO), but the embodiments of the present specification are not limited thereto.

The encapsulation layer 136 may be disposed on at least a portion of the first semiconductor layer 131, the active layer 132, the second semiconductor layer 133, the anode electrode 134, and the cathode electrode 135. For example, the encapsulation layer 136 may surround at least a portion of the first semiconductor layer 131, the active layer 132, the second semiconductor layer 133, the anode electrode 134, and the cathode electrode 135.

For example, the encapsulation layer 136 may protect the first semiconductor layer 131, the active layer 132, and the second semiconductor layer 133. For example, the encapsulation layer 136 may be disposed on a side surface of the first semiconductor layer 131, a side surface of the active layer 132, and a side surface of the second semiconductor layer 133.

For example, the encapsulation layer 136 may be disposed on at least a portion of the anode electrode 134 and the cathode electrode 135, for example, an edge portion (or one side) of the anode electrode 134 and an edge portion (or one side) of the cathode electrode 135. At least a portion of the anode electrode 134 may be exposed from the encapsulation layer 136, and the anode electrode 134 and the solder pattern SDP may be connected. For example, at least a portion of the cathode electrode 135 may be exposed from the encapsulation layer 136, and the cathode electrode 135 and the second electrode CE2 may be connected. For example, the encapsulation layer 136 may be made of an insulating material such as silicon nitride (SiNx) or silicon oxide (SiOx), but the embodiments of the present specification are not limited thereto.

In another example, the encapsulation layer 136 may have a structure in which a reflecting material is dispersed in a resin layer, but the embodiments of the present specification are not limited thereto. For example, the encapsulation layer 136 may be manufactured as a reflector of various structures, but the embodiments of the present specification are not limited thereto. Light emitted from the active layer 132 may be reflected upward by the encapsulation layer 136, and light extraction efficiency may be improved. For example, the encapsulation layer 136 may be a reflective layer, but the embodiments of the present specification are not limited thereto.

According to the present specification, the light emitting diode ED has been described as having a vertical type structure, but the embodiments of the present specification are not limited thereto. For example, the light emitting diode ED may have a lateral structure or a flip chip structure.

The first light emitting diode 130 has been described above with reference to FIG. 10, but the second light emitting diode 140 and the third light emitting diode 150 may have substantially the same structure as the first light emitting diode 130. For example, the second light emitting diode 140 and the third light emitting diode 150 may each include a first semiconductor layer 131, an active layer 132, a second semiconductor layer 133, an anode electrode 134, a cathode electrode 135, and an encapsulation layer 136 that are substantially the same as those of the first light emitting diode 130.

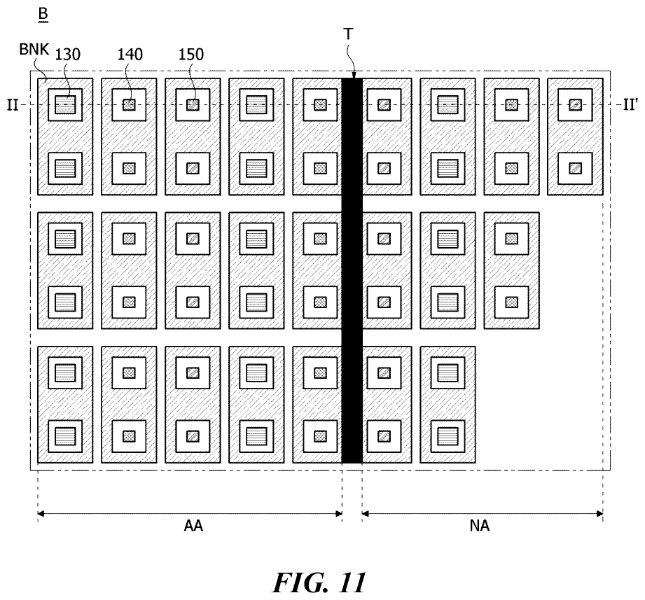

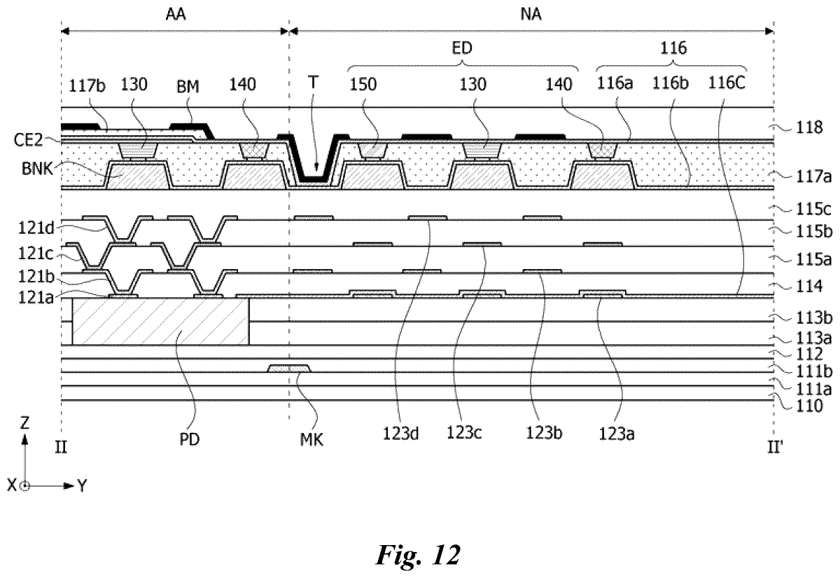

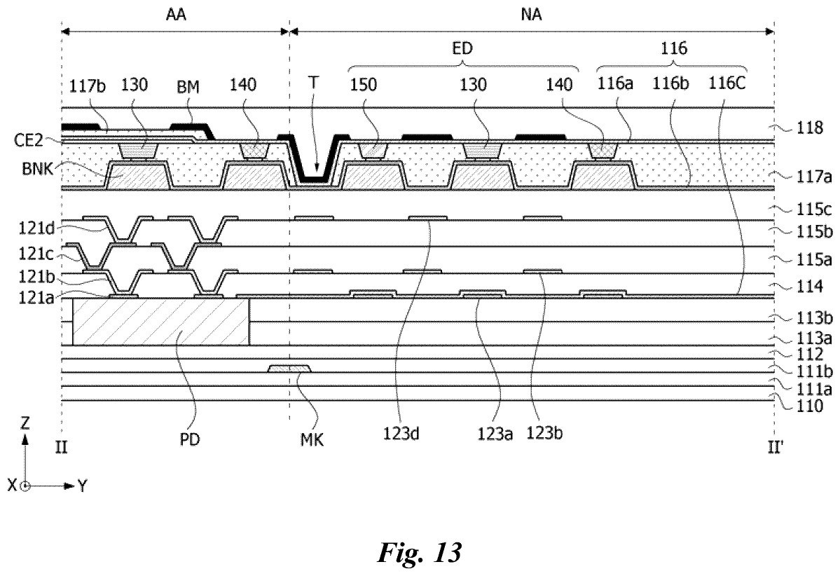

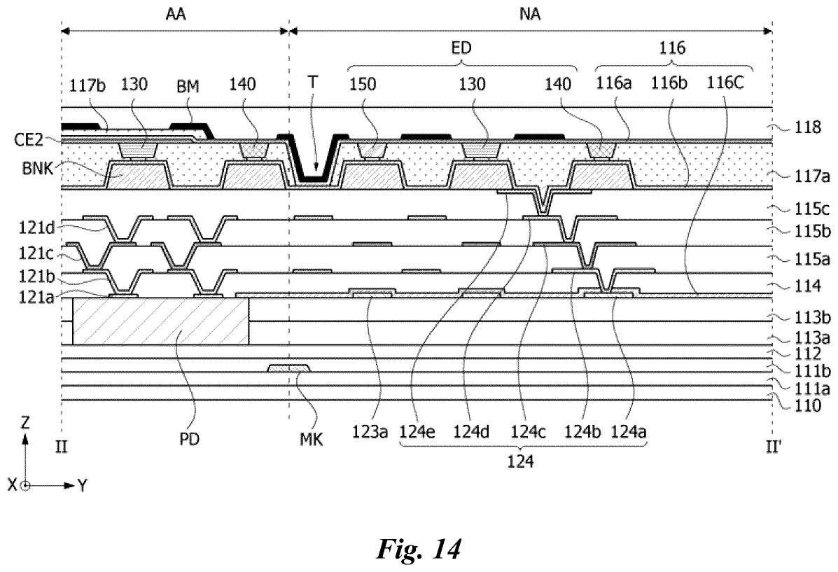

FIG. 11 is a partially enlarged view showing portion B of FIG. 3 in an enlarged manner. FIG. 12 is a cross-sectional view of the display device according to an embodiment of the present specification that is along line II-II′ of FIG. 11. FIG. 13 is a cross-sectional view of the display device according to a second embodiment of the present specification that is along line II-II′ of FIG. 11. FIG. 14 is a cross-sectional view of the display device according to a third embodiment of the present specification that is along line II-II′ of FIG. 11.

Referring to FIGS. 11 and 12, a display device according to an embodiment of the present specification may include a display area AA and a non-display area NA. The display area AA may include a plurality of light emitting diodes 130, 140, and 150, a second electrode CE2, a first optical layer 117a, a second optical layer 117b, and a third optical layer 117c. The non-display area NA may include a plurality of light emitting diodes 130, 140, and 150, a first optical layer 117a, a second optical layer 117b, and a third optical layer 117c.

The plurality of light emitting diodes 130, 140, and 150 disposed in the display area AA may emit light due to a high-potential power voltage applied to a first electrode as a plurality of second electrodes CE2 are disposed. The second electrode CE2 may be formed to entirely cover a plurality of pixels to be common to the plurality of pixels. The second electrode CE2 may be formed to be common only to the plurality of light emitting diodes 130, 140, and 150 disposed on each pixel.

The plurality of light emitting diodes 130, 140, and 150 disposed in the display area AA and the non-display area NA may include a first light emitting diode 130, a second light emitting diode 140, and a third light emitting diode 150. The first light emitting diode 130, the second light emitting diode 140, and the third light emitting diode 150 may implement a first color, a second color, and a third color, respectively. The first to third colors may be any one selected from red, green, and blue to not overlap one another, but the embodiments of the present specification are not limited thereto. For example, the first color may be red, the second color may be green, and the third color may be blue, but the present specification is not limited thereto.

The non-display area NA may include a dummy area. The dummy area may include a dummy pixel including a plurality of dummy light emitting diodes. The second electrode CE2 may not be disposed in the non-display area NA in which the plurality of dummy light emitting diodes are disposed. Therefore, even when a high-potential power voltage is applied to the first electrode disposed on the dummy light emitting diode, the dummy light emitting diode may not be able to emit light.

A trench T may be disposed between the plurality of light emitting diodes 130, 140, and 150. The trench T may be disposed between the second light emitting diode 140 and the third light emitting diode 150, but the present specification is not limited thereto. Since the trench is disposed between the second light emitting diode 140 and the third light emitting diode 150 having a relatively small size, a design margin of the display panel can be secured. Therefore, the probability of defective transfer of a light emitting diode can be reduced in a process of manufacturing the display panel. Thus, the productivity of the display device can be improved. In addition, since the trench T is disposed, the display panel may be protected. For example, effects such as prevention of moisture permeation can be implemented. Therefore, the reliability of the display device can be improved.

Referring to FIGS. 12 to 14, the display device 1000 may include the plurality of light emitting diodes 130, 140, and 150 disposed in the display area AA and the non-display area NA.

A circuit layer disposed in the display area AA may include a pixel driving circuit PD and a plurality of first driving lines 121. The plurality of first driving lines 121 may include a (1-1)-th driving line 121a, a (1-2)-th driving line 121b, a (1-3)-th driving line 121c, and a (1-4)-th driving line 121d, but the embodiments of the present specification are not limited thereto.

Each of the first driving lines 121a, 121b, 121c, and 121d may be electrically connected through a contact hole disposed in the circuit layer.

A third passivation layer 116c may be disposed between the second protective layer 113b and the third protective layer 114. The third passivation layer 116c may be formed on at least a portion of an upper portion of the pixel driving circuit PD of the display area AA and on the non-display area NA. The third passivation layer 116c may be formed to entirely cover the second protective layer 113b in the non-display area NA. The third passivation layer 116c may protect the display device 1000 from penetration of moisture from outside the display device 1000, and the reliability of the display device 1000 can be improved.

A plurality of non-driving lines 123 and 124 may be disposed on a circuit layer disposed in the non-display area NA. The non-driving lines may include a dummy floating line 123 and a moisture penetration preventing line 124. The non-driving lines 123 and 124 may be disposed to be electrically separated from the pixel driving circuit PD.

The dummy floating line 123 may include a first dummy floating line 123a, a second dummy floating line 123b, a third dummy floating line 123c, and a fourth dummy floating line 123d, but the embodiments of the present specification are not limited thereto.

For example, a plurality of first dummy floating lines 123a may be disposed on the second protective layer 113b. The plurality of first dummy floating lines 123a may be disposed to be electrically separated from the pixel driving circuit PD and other dummy floating lines 123 to reduce a step difference between an organic material layer of the display area AA and an organic material layer of the non-display area NA.

The second dummy floating line 123b may be disposed on the third protective layer 114. A plurality of second dummy floating lines 123b may be disposed to be electrically separated from the pixel driving circuit PD and other dummy floating lines 123.

Likewise, the third dummy floating line 123c and the fourth dummy floating line 123d may be disposed to be electrically separated from the pixel driving circuit PD and other dummy floating lines 123 while disposed on the first insulating layer 115a and the second insulating layer 115b, respectively, the embodiments of the present specification are not limited thereto.

For example, the first dummy floating line 123a may be disposed at a position overlapping the plurality of light emitting diodes 130, 140, and 150 on the second protective layer 113b in the height direction of the display device 1000 (for example, the Z-axis direction).

The second dummy floating line 123b may be disposed at a position not overlapping the plurality of light emitting diodes 130, 140, and 150 on the third protective layer 114 in the height direction of the display device 1000.

The third dummy floating line 123c may be disposed at a position overlapping the plurality of light emitting diodes 130, 140, and 150 on the first insulating layer 115a in the height direction of the display device 1000.

The fourth dummy floating line 123d may be disposed at a position not overlapping the plurality of light emitting diodes 130, 140, and 150 on the second protective layer 113b in the height direction of the display device 1000. Ultimately, the first to fourth dummy floating lines 123a, 123b, 123c, and 123d may be disposed in a zigzag manner so as not to overlap one another in the cross-sectional view of the display panel shown in FIG. 13.

In the non-display area NA, the dummy floating lines 123 may be disposed to reduce the step difference between the organic material layer of the display area AA and the organic material layer of the non-display area NA. Since the step difference between the display area AA and the non-display area NA is reduced, in transfer of the light emitting diodes 130, 140, and 150 at an outer boundary of the display area AA disposed adjacent to the non-display area NA, non-transfer due to the step difference between the organic material layers can be prevented.

Some of the plurality of dummy floating lines 123 may be omitted. For example, as in FIG. 13, the third dummy floating line 123c disposed on the first insulating layer 115a may be omitted, and only the other dummy floating lines 123a, 123b, and 123d may be disposed in the non-display area NA. The embodiments of the present specification are not limited thereto, and at least one or more of the first dummy floating line 123a, the second dummy floating line 123b, and the fourth dummy floating line 123d may be omitted, and only the remaining dummy floating line may be disposed in the non-display area NA.

Referring to FIG. 14, a plurality of moisture penetration preventing lines 124 may be disposed on an outer boundary of the non-display area NA.

The plurality of moisture penetration preventing lines 124 may be disposed on the outer boundary of the non-display area NA to prevent moisture from the outside that has penetrated due to the insulating layers 115 and the protective layers 113 and 114, which are vulnerable to moisture, from penetrating into the display area AA.

For example, a first moisture penetration preventing line 124a may be disposed on the second protective layer 113b. The first dummy floating line 123a may be used as the first moisture penetration preventing line 124a. A second moisture penetration preventing line 124b may be disposed on the third protective layer 114 and may be disposed to be connected to the first moisture penetration preventing line 124a through contact holes formed in the third protective layer 114 and the third passivation layer 116c.

A third moisture penetration preventing line 124c may be disposed on the first insulating layer 115a and may be disposed to be connected to the second moisture penetration preventing line 124b through a contact hole formed in the first insulating layer 115a.

A fourth moisture penetration preventing line 124d may be disposed on the second insulating layer 115b and may be disposed to be connected to the third moisture penetration preventing line 124c through a contact hole formed in the second insulating layer 115b.

A fifth moisture penetration preventing line 124e may be disposed by etching a portion of the third insulating layer 115c and may be disposed to be connected to the fourth moisture penetration preventing line 124d through a contact hole formed in the third insulating layer 115c.

The contact holes each connecting one of the moisture penetration preventing lines 124 may be disposed to not overlap in the height direction of the display device. Referring to the coordinate system, each of the moisture penetration preventing lines 124 may be disposed to be longer than a length of the dummy floating lines 123, which are disposed in the non-display area NA, in the Y-axis direction of the display device.

In addition, at least one of the non-driving lines 123 and 124 may be disposed as a ground line to which a ground (GND) voltage is applied.

The plurality of dummy floating lines 123 and the plurality of moisture penetration preventing lines 124 may be formed of a conductive material with excellent flexibility like the plurality of first driving lines 121 and the plurality of second driving lines 122 or any one of various conductive materials used in the display area AA. For example, the plurality of dummy floating lines 123 and the plurality of moisture penetration preventing lines 124 may be made of a conductive material with excellent flexibility such as gold (Au), silver (Ag), or aluminum (Al), but the embodiments of the present specification are not limited thereto. In another example, the dummy floating lines 123 may be made of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto.

The display device may include a trench T. Referring to the coordinate system, the trench T may be disposed to extend in a first direction (for example, the X-axis direction). The non-display area NA may include the trench T. The trench T may be formed between the plurality of light emitting diodes 130, 140, and 150. The trench T may be formed between the plurality of dummy light emitting diodes (the plurality of light emitting diodes disposed in the non-display area NA).

The first optical layer 117a formed in the non-display area NA may include the trench T. The second optical layer 117b formed in the non-display area NA may include the trench T. The trench T may be formed by removing at least a portion of the first optical layer 117a and/or the second optical layer 117b. The first passivation layer 116a may be disposed on the trench T. At least a portion of the black matrix BM may be disposed on the trench T.

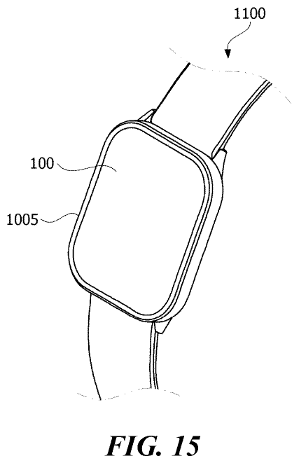

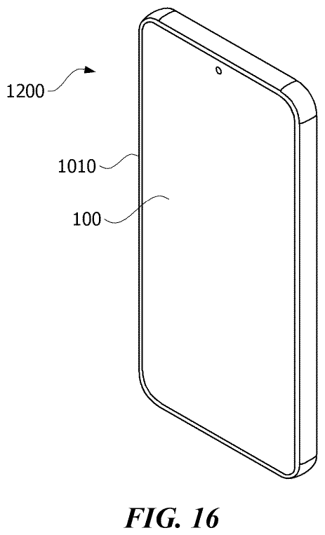

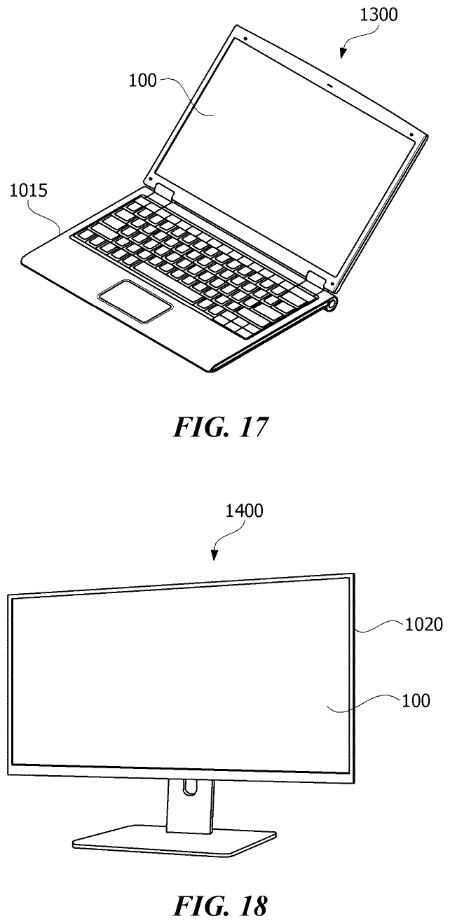

FIGS. 15 to 18 are views illustrating devices to which the display device according to embodiments of the present specification is applied.

Referring to FIGS. 15 to 18, the display device 1000 according to embodiments of the present specification may be included in various devices or electronic devices. For example, referring to FIGS. 15 to 18, various electronic devices may include a wearable device 1100, a mobile device 1200, a laptop 1300, and a monitor or TV 1400, but the embodiments of the present specification are not limited thereto.

The wearable device 1100, the mobile device 1200, the laptop 1300, and the monitor or TV 1400 may include case portions 1005, 1010, 1015, and 1020, respectively, and the display panel 100 (or the display device 1000) according to the embodiments of the present specification described above.

For example, the display device according to an embodiment of the present specification may be applied to a mobile device, a video phone, a smartwatch, a watch phone, a wearable device, a foldable apparatus, a rollable apparatus, a bendable apparatus, a flexible apparatus, a curved apparatus, a sliding apparatus, a variable apparatus, an electronic organizer, an electronic book, a portable multimedia player (PMP), a personal digital assistant (PDA), an MP3 player, a mobile medical apparatus, a desktop PC, a laptop PC, a netbook computer, a workstation, a navigation, a vehicle display device, a theater display device, a TV, a wallpaper apparatus, a signage apparatus, a game apparatus, a laptop, a monitor, a camera, a camcorder, a home appliance, etc.

A display panel and a display device including the same according to one or more embodiments of the present specification may be described as below.

A display panel according to an embodiment of the present specification may include a circuit layer disposed on a substrate and a plurality of light emitting diodes disposed on the circuit layer, wherein the circuit layer may include a plurality of driving lines disposed on the substrate and electrically connected to the light emitting diodes disposed in a display area among the plurality of light emitting diodes and a plurality of non-driving lines disposed on the substrate in a non-display area outside the display area, and at least one of the non-driving lines may include a plurality of dummy floating lines electrically separated from the light emitting diodes and the driving lines.

In the display panel according to an embodiment, the circuit layer may further include a plurality of protective layers disposed on the substrate and a plurality of insulating layers disposed on the protective layers.

In the display panel according to an embodiment, the circuit layer may further include a pixel driving circuit electrically connected to the light emitting diodes disposed in the display area through the driving lines disposed on the insulating layers.

In the display panel according to an embodiment, the non-driving lines may be electrically separated from the pixel driving circuit.

In the display panel according to an embodiment, a ground voltage may be applied to at least one of the non-driving lines.

In the display panel according to an embodiment, the non-driving lines may further include a plurality of first dummy floating lines disposed on the protective layers.

In the display panel according to an embodiment, the non-driving lines may further include a plurality of second dummy floating lines disposed on an upper portion of an insulating layer disposed on the first dummy floating lines among the plurality of insulating layers, a third dummy floating line disposed on an upper portion of an insulating layer disposed on the second dummy floating line among the plurality of insulating layers, and a fourth dummy floating lines disposed on an upper portion of an insulating layer disposed on the third dummy floating lines among the plurality of insulating layers.

In the display panel according to an embodiment, the first dummy floating line, the second dummy floating line, the third dummy floating line, and the fourth dummy floating line may each be electrically separated.

In the display panel according to an embodiment, the first dummy floating line and the second dummy floating line may be disposed to not overlap in a height direction of the substrate, the second dummy floating line and the third dummy floating line may be disposed to not overlap in the height direction of the substrate, and the third dummy floating line and the fourth dummy floating line may be disposed to not overlap in the height direction of the substrate.

In the display panel according to an embodiment, the first dummy floating line and the third dummy floating line may be disposed to overlap the light emitting diodes disposed in the non-display area among the plurality of light emitting diodes in the height direction of the substrate.

In the display panel according to an embodiment, the second dummy floating line and the fourth dummy floating line may be disposed to not overlap the light emitting diodes disposed in the non-display area among the plurality of light emitting diodes in the height direction of the substrate.

In the display panel according to an embodiment, the non-driving lines may further include a plurality of moisture penetration preventing lines.

In the display panel according to an embodiment, the moisture penetration preventing lines may be connected to each other through a contact hole disposed in the circuit layer.

In the display panel according to an embodiment, the moisture penetration preventing line may be connected to the first dummy floating line through a contact hole disposed in the circuit layer.

In the display panel according to an embodiment, the light emitting diodes may include a first light emitting diode emitting light in a first wavelength band, a second light emitting diode emitting light in a second wavelength band, and a third light emitting diode emitting light in a third wavelength band, and a size of at least one of the first light emitting diode, the second light emitting diode, and the third light emitting diode may be different from a size of another light emitting diode.

In the display panel according to an embodiment, the size of the first light emitting diode may be larger than the size of each of the second light emitting diode and the third light emitting diode.

In the display panel according to an embodiment, the sizes of the second light emitting diode and the third light emitting diode may be the same.

In the display panel according to an embodiment, all of the first light emitting diode, the second light emitting diode, and the third light emitting diode may be inorganic light emitting diodes.

In the display panel according to an embodiment, a trench may be disposed between the second light emitting diode and the third light emitting diode neighboring the same, in the non-display area.

In the display panel according to an embodiment, the first light emitting diode may further include an anode electrode, a first semiconductor layer disposed on the anode electrode, an active layer disposed on the first semiconductor layer, a second semiconductor layer disposed on the active layer, a cathode electrode disposed on the second semiconductor layer, and a solder pattern disposed on a lower portion of the anode electrode, the anode electrode may be electrically connected through eutectic bonding using the solder pattern, and a structure of each of the second light emitting diode and the third light emitting diode may be the same as a structure of the first light emitting diode.

According to an embodiment of the present specification, by decreasing a proportion of defectively transferred light emitting diodes during transfer of light emitting diodes to a panel of a display device, reliability can be secured.

According to an embodiment of the present specification, by protecting a display device from penetration of moisture from the outside, the reliability of the display device can be improved.

By preventing permeation of moisture into a display device from the outside, the service life of the display device can be improved. Thus, in the long-term, operation can be performed with reduced power consumption and low power.

Effects of the present specification are not limited to those mentioned above, and other unmentioned effects should be clearly understood by those of ordinary skill in the art to which the technical spirit of the present specification pertains from the content described herein.

Although the embodiments of the present disclosure have been described in more detail with reference to the accompanying drawings, the present disclosure is not limited thereto and may be embodied in many different forms without departing from the technical concept of the present disclosure.

Therefore, the embodiments disclosed in the present disclosure are provided for illustrative purposes only and are not intended to limit the technical concept of the present disclosure.

The scope of the technical concept of the present disclosure is not limited thereto.

Therefore, it should be understood that the above-described embodiments are illustrative in all aspects and do not limit the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a circuit layer disposed on a substrate; and
a plurality of light emitting diodes disposed on the circuit layer,
wherein the circuit layer includes a plurality of driving lines disposed on the substrate and electrically connected to light emitting diodes disposed in a display area among the plurality of light emitting diodes and a plurality of non-driving lines disposed on the substrate in a non-display area outside the display area, and
at least one of the plurality of non-driving lines includes a plurality of dummy floating lines electrically separated from the light emitting diodes and the plurality of driving lines.

2. The display panel of claim 1, wherein the circuit layer further includes:
a plurality of protective layers disposed on the substrate; and
a plurality of insulating layers disposed on the protective layers.

3. The display panel of claim 2, wherein the circuit layer further includes a pixel driving circuit electrically connected to the light emitting diodes disposed in the display area through driving lines of the plurality of driving lines that are disposed on the insulating layers.

4. The display panel of claim 3, wherein the plurality of non-driving lines are electrically separated from the pixel driving circuit.

5. The display panel of claim 1, wherein a terminal of a ground voltage is connected to at least one of the non-driving lines.

6. The display panel of claim 2, wherein the plurality of non-driving lines further include a plurality of first dummy floating lines disposed on the plurality of protective layers.

7. The display panel of claim 6, wherein the plurality of non-driving lines further include:
a plurality of second dummy floating lines disposed on an upper portion of an insulating layer disposed on the first dummy floating lines among the plurality of insulating layers;
a plurality of third dummy floating lines disposed on an upper portion of an insulating layer disposed on the second dummy floating lines among the plurality of insulating layers; and
a plurality of fourth dummy floating lines disposed on an upper portion of an insulating layer disposed on the third dummy floating lines among the plurality of insulating layers.

8. The display panel of claim 7, wherein the first dummy floating lines, the second dummy floating lines, the third dummy floating lines, and the fourth dummy floating lines are each electrically separated.

9. The display panel of claim 8, wherein:
the first dummy floating line and the second dummy floating line do not overlap in a height direction of the substrate,
the second dummy floating line and the third dummy floating line do not overlap in the height direction of the substrate, and
the third dummy floating line and the fourth dummy floating line do not overlap in the height direction of the substrate.

10. The display panel of claim 7, wherein the first dummy floating line and the third dummy floating line overlap the light emitting diodes disposed in the non-display area among the plurality of light emitting diodes in a height direction of the substrate.

11. The display panel of claim 7, wherein the second dummy floating line and the fourth dummy floating line do not overlap the light emitting diodes disposed in the non-display area among the plurality of light emitting diodes in a height direction of the substrate.

12. The display panel of claim 6, wherein the non-driving lines further include a plurality of moisture penetration preventing lines.

13. The display panel of claim 12, wherein the moisture penetration preventing lines are connected to each other through a contact hole disposed in the circuit layer.

14. The display panel of claim 12, wherein the moisture penetration preventing line is connected to the first dummy floating lines through a contact hole disposed in the circuit layer.

15. The display panel of claim 1, wherein:
the light emitting diodes include a first light emitting diode emitting light in a first wavelength band, a second light emitting diode emitting light in a second wavelength band, and a third light emitting diode emitting light in a third wavelength band; and
a size of at least one of the first light emitting diode, the second light emitting diode, or the third light emitting diode is different from a size of another light emitting diode.

16. The display panel of claim 15, wherein a size of the first light emitting diode is larger than a size of each of the second light emitting diode and the third light emitting diode.

17. The display panel of claim 15, wherein the sizes of the second light emitting diode and the third light emitting diode are same.

18. The display panel of claim 15, wherein all of the first light emitting diode, the second light emitting diode, and the third light emitting diode are inorganic light emitting diodes.

19. The display panel of claim 15, comprising a trench disposed between the second light emitting diode and the third light emitting diode neighboring the second light emitting diode, in the non-display area.

20. The display panel of claim 15, wherein:
the first light emitting diode further includes an anode electrode, a first semiconductor layer disposed on the anode electrode, an active layer disposed on the first semiconductor layer, a second semiconductor layer disposed on the active layer, a cathode electrode disposed on the second semiconductor layer, and a solder pattern disposed on a lower portion of the anode electrode,
the anode electrode is electrically connected through eutectic bonding using the solder pattern, and
a structure of each of the second light emitting diode and the third light emitting diode is same as a structure of the first light emitting diode.
